(19) United States
(12) Patent Application Publication
(10) Pub. No.: US 2025/0244507 A1
(43) Pub. Date: Jul. 31, 2025

(54) IMAGE SENSOR INCLUDING PATTERNED ANTI-REFLECTION LAYER AND MANUFACTURING METHOD THEREOF

(71) Applicant: SAMSUNG ELECTRONICS CO., LTD., Suwon-si (KR)

(72) Inventors: Hyeonsoo PARK, Suwon-si (KR); Hongkyu PARK, Suwon-si (KR); Byunghong CHUNG, Suwon-si (KR); Sookyoung ROH, Suwon-si (KR); Sungmo AHN, Suwon-si (KR); Choonlae CHO, Suwon-si (KR)

(73) Assignee: SAMSUNG ELECTRONICS CO., LTD., Suwon-si (KR)

(21) Appl. No.: 19/024,748

(22) Filed: Jan. 16, 2025

(30) Foreign Application Priority Data
Jan. 25, 2024 (KR) 10-2024-0011851

(51) Int. Cl. G02B 1/118; G02B 27/10

(52) U.S. Cl. CPC G02B 1/118; G02B 27/1013

(57) ABSTRACT

Provided are an image sensor including a patterned anti-reflection layer and an electronic device including the image sensor. The image sensor includes a nano optical lens array including a plurality of color separation nano structures configured to separate incident light according to wavelengths and condense the separated light at respective corresponding pixels among a plurality of pixels and an anti-reflection layer arranged on a light incidence surface of the nano optical lens array and including a plurality of first nano patterns and a plurality of second nano patterns, which are cyclically arranged in a two-dimensional manner. The plurality of second nano patterns are arranged between the plurality of first nano patterns, and a width of each of the plurality of first nano patterns is greater than a width of each of the plurality of second nano patterns.

### CROSS-REFERENCE TO RELATED APPLICATION

This application is based on and claims priority under 35 U.S.C. § 119 to Korean Patent Application No. 10-2024-0011851, filed on Jan. 25, 2024, in the Korean Intellectual Property Office, the disclosure of which is incorporated by reference herein in its entirety.

### BACKGROUND

### 1. Field

The disclosure relates to an image sensor, and in particular, to an image sensor including a patterned anti-reflection layer and a manufacturing method of the image sensor.

### 2. Description of the Related Art

Image sensors generally sense colors of incident light by using a color filter. However, as a color filter absorbs light of all other colors except for light of one particular color, the light utilization efficiency may decline. For example, in an RGB color filter, only ⅓ of incident light is transmitted, and the other ⅔ is absorbed. Accordingly, the light utilization efficiency of the RGB color filter may be merely about 33%, which means a large portion of incident light is lost and/or not used. Recently, various efforts have been made to improve the light utilization efficiency of image sensors.

In addition, as image sensors include multiple layers having different refractive indexes from each other, incident light may be reflected at boundaries of the layers. Having a low reflectance with respect to incident light may be advantageous in image sensors to improve the light utilization efficiency of the image sensors.

### SUMMARY

Provided are an image sensor including a patterned anti-reflection layer and a manufacturing method of the image sensor.

Additional aspects will be set forth in part in the description which follows and, in part, will be apparent from the description, or may be learned by practice of the presented embodiments of the disclosure.

According to an aspect of the disclosure, there is provided an image sensor including: a substrate including a plurality of pixels sensing light; a nano optical lens array provided on the substrate, the nano optical lens array including a plurality of color separation nano structures configured to separate incident light based on wavelengths and condense the separated light at respective corresponding pixels among the plurality of pixels; and an anti-reflection layer provided on a light incidence surface of the nano optical lens array, the anti-reflection layer including a plurality of first nano patterns and a plurality of second nano patterns, which are periodically arranged in a two-dimensional manner, wherein each of the plurality of second nano patterns are arranged between two adjacent first nano patterns, among the plurality of first nano patterns, and a width of each of the plurality of first nano patterns is greater than a width of each of the plurality of second nano patterns.

The anti-reflection layer may include a plurality of unit regions, wherein the plurality of first nano patterns are arranged in the plurality of unit regions, wherein the plurality of second nano patterns are arranged at boundaries of the plurality of unit regions, and wherein the width of each of the plurality of first nano patterns is at least two times the width of each of the plurality of second nano patterns.

The anti-reflection layer may include: a first unit region, a second unit region, a third unit region, and a fourth unit region provided in a first row and a second row, wherein the first unit region and the second unit region are adjacent to each other in the first row in a first direction, the third unit region and fourth unit region are adjacent to each other in the second row in the first direction, and the first row and the second row are adjacent to each other in a second direction, and wherein the plurality of first nano patterns are provided in the first, second, third, and fourth unit regions, and the plurality of second nano patterns are provided at boundaries of the first, second, third, and fourth unit regions.

The width of each of the plurality of first nano patterns is about 150 nm to about 200 nm.

The width of each of the plurality of second nano patterns is about 75 nm to about 100 nm.

A distance between each of the plurality of first nano patterns and an adjacent second nano pattern, among the plurality of second nano patterns is about 20 nm to about 50 nm.

A width of each of the plurality of unit regions is about 200 nm to about 300 nm.

A fill factor of the plurality of first nano patterns in the plurality of unit regions is about 30% to about 70%, and the fill factor is a ratio of a cross-sectional area of the plurality of first nano patterns to a cross-sectional area of the plurality of unit regions.

The nano optical lens array may include: a first layer meta region and a second layer meta region provided on the first layer meta region, wherein the first layer meta region includes a plurality of first layer nano structures, and wherein the second layer meta region includes a plurality of second layer nano structures.

At a peripheral portion of the image sensor, the first layer meta region and the second layer meta region of the nano optical lens array and the plurality of unit regions of the anti-reflection layer are shifted towards a central portion of the image sensor.

At the peripheral portion of the image sensor, a shift distance of the plurality of unit regions is greater than a shift distance of the plurality of second layer meta regions, and the shift distance of the plurality of second layer meta regions is greater than a shift distance of the first layer meta region.

The anti-reflection layer may include: a first unit region in which incident light is incident at a first chief ray angle and a second unit region in which the incident light is incident at a second chief ray angle, which is greater than the first chief ray angle, and a width of each of the plurality of first nano patterns arranged in the second unit region is greater than a width of each of the plurality of first nano patterns arranged in the first unit region.

The anti-reflection layer may include: a first unit region in which incident light is incident at a first chief ray angle and a second unit region in which the incident light is incident at a second chief ray angle, which is greater than the first chief ray angle, wherein a cross-section of each of the plurality of first nano patterns arranged in the first unit region is circular, and a cross-section of each of the plurality of first nano patterns arranged in the second unit region is elliptical.

The anti-reflection layer may further include: a third unit region in which the incident light is incident at a third chief ray angle, which is greater than the second chief ray angle, wherein a cross-section of each of the plurality of first nano patterns arranged in the third unit region is elliptical, and an eccentricity of the plurality of first nano patterns arranged in the third unit region is greater than an eccentricity of the plurality of first nano patterns arranged in the second unit region.

The image sensor may further include: a color filter layer provided between the substrate and the nano optical lens array; and a planarization layer provided between the color filter layer and the nano optical lens array.

The anti-reflection layer may include at least one of AlO, HfO, SiN, SiO₂, AlOC, AlON, or AlOCN.

The anti-reflection layer may include an inorganic material having a refractive index of about 1 to about 3.

According to another aspect of the disclosure, there is provided a method of manufacturing an image sensor, the method may include: providing a nano optical lens array including a plurality of color separation nano structures on a substrate; and providing an anti-reflection layer on the nano optical lens array, wherein the arranging of the anti-reflection layer may include: arranging a dielectric layer on the nano optical lens array; patterning a plurality of first nano patterns having a first width in the dielectric layer; and patterning a plurality of second nano patterns having a second width less than the first width, in the dielectric layer, wherein each of the plurality of second nano patterns are arranged between two adjacent first nano patterns, among the plurality of first nano patterns.

The patterning of the plurality of first nano patterns may include: forming a photoresist layer on the dielectric layer; selectively exposing a portion of an upper surface of the dielectric layer and patterning the photoresist layer using a photomask; and forming the plurality of first nano patterns by etching the portion of the upper surface of the dielectric layer using the photoresist layer as an etching mask.

The patterning of the plurality of second nano patterns may include: forming a photoresist layer on the dielectric layer; forming an opening in the photoresist layer to selectively expose a portion of an upper surface of the dielectric layer and patterning the photoresist layer using a photomask; forming a spacer layer on the photoresist layer to reduce a width of the opening of the photoresist layer; and forming the plurality of second nano patterns by etching the portion of the upper surface of the dielectric layer using the photoresist layer and the spacer layer as an etching mask.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 is a schematic block diagram of an image sensor according to an embodiment;

FIG. 2 is a diagram illustrating an example of a pixel arrangement of a pixel array of an image sensor, according to an embodiment;

FIG. 3 is a schematic perspective view of a configuration of a pixel array of an image sensor, according to an embodiment;

FIG. 4 is a schematic plan view of a configuration of a sensor substrate of the pixel array illustrated in FIG. 3;

FIG. 5 is a schematic plan view of a configuration of a color filter layer illustrated in FIG. 3;

FIG. 6 is a plan view illustrating an example of a configuration of a nano optical lens array illustrated in FIG. 3;

FIG. 7 is a diagram showing phase profiles of green light and blue light, which have passed through a nano optical lens array;

FIG. 8 is a diagram showing phase profiles of red light and green light, which have passed through a nano optical lens array;

FIG. 9 is a plan view illustrating an example of a configuration of an anti-reflection layer;

FIG. 10 is a plan view illustrating another example of a configuration of an anti-reflection layer;

FIG. 11 is a diagram illustrating an example of positions of a central portion and a peripheral portion of a pixel array at which angles of chief ray of incident light are different from each other;

FIGS. 12A and 12B are cross-sectional views schematically showing a cross-sectional structure of a pixel array at a central portion of the pixel array, according to an embodiment;

FIGS. 13A and 13B are cross-sectional views schematically showing a cross-sectional structure of a pixel array at a peripheral portion of the pixel array, according to an embodiment;

FIG. 14 is a diagram illustrating an example of relative positions of a sensor substrate, a color filter layer, a nano optical lens array, and first and second nano patterns of an anti-reflection layer, at a peripheral portion of a pixel array, according to an embodiment;

FIGS. 15A and 15B are cross-sectional views schematically showing a cross-sectional structure of a pixel array at a central portion of a pixel array, according to another embodiment;

FIGS. 16A and 16B are cross-sectional views schematically showing a cross-sectional structure of a pixel array at a peripheral portion of a pixel array, according to another embodiment;

FIG. 17 is a diagram illustrating an example of relative positions of a sensor substrate, a color filter layer, first and second layer meta regions, and first and second nano patterns of an anti-reflection layer, at a peripheral portion of a pixel array, according to another embodiment;

FIG. 18 is a diagram illustrating changes in shapes of nano patterns of an anti-reflection layer at different positions on a pixel array, according to an embodiment;

FIGS. 19A to 19D are schematic cross-sectional views illustrating a manufacturing method of an image sensor, according to an embodiment;

FIGS. 20A to 20D are diagrams illustrating a manufacturing method of a first nano pattern;

FIGS. 21A to 21E are diagrams illustrating a manufacturing method of a second nano pattern;

FIG. 22 is a schematic block diagram of an electronic device including an image sensor, according to an embodiment;

FIG. 23 is a schematic block diagram of a camera module of FIG. 22;

FIG. 24 is a block diagram of an electronic device including a multi-camera module; and

FIG. 25 is a detailed block diagram of the multi-camera module of the electronic device illustrated in FIG. 24.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, an image sensor including a patterned anti-reflection layer and an electronic device including the image sensor will be described in detail with reference to the accompanying drawings. The embodiments described herein are provided merely as an example, and various modifications may be possible from the embodiments. In the drawings, like reference numerals in the drawings denote like elements, and sizes of components in the drawings may be exaggerated for clarity and convenience of explanation.

When a component is “on,” “on the top of,” etc. another component, it shall be understood that not only the component may be directly on, under, on the left of, or on the right of another component, but also it may be on, under, on the left of, or on the right of another component in a non-contact manner.

While such terms as “first,” “second,” etc., may be used to describe various components, such terms are used only to distinguish one component from another. These terms are not intended to define that materials or structures of components are different.

An expression used in the singular encompasses the expression of the plural, unless it has a clearly different meaning in the context. When a portion “includes” an element, another element may be further included, rather than excluding the existence of the other element, unless otherwise described.

In addition, the terms “ . . . portion,” “module,” etc., described in the specification refer to a unit for processing a function or operation, which can be implemented by a hardware or a software, or a combination of a hardware and a software.

The use of the terms “a” and “an” and “the” and similar referents in the context of describing embodiments (especially in the context of the following claims) are to be construed to cover both the singular and the plural.

Also, the steps of all methods described herein can be performed in any suitable order unless otherwise indicated herein or otherwise clearly contradicted by context. The use of any and all exemplary languages (e.g., “such as”) provided herein, are intended merely to better illuminate the technical ideas and does not pose a limitation on the scope of rights unless otherwise claimed.

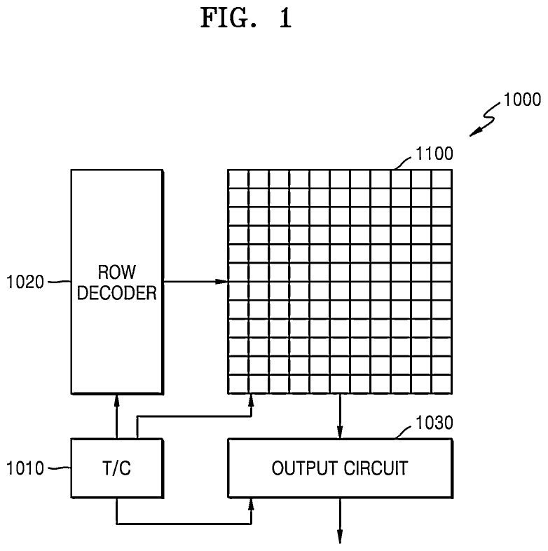

FIG. 1 is a schematic block diagram of an image sensor according to an embodiment. Referring to FIG. 1, an image sensor 1000 may include a pixel array 1100, a timing controller (T/C) 1010, a row decoder 1020, and an output circuit 1030. The image sensor may be a charge coupled device (CCD) image sensor or a complementary metal oxide semiconductor (CMOS) image sensor.

The pixel array 1100 may include pixels arranged in a two-dimensional manner in a plurality of rows and columns. The row decoder 1020 may select one of the rows of the pixel array 1100 in response to a row address signal output from the timing controller 1010. The output circuit 1030 may output a light sensing signal by the column from a plurality of pixels arranged along the selected row. To this end, the output circuit 1030 may include a column decoder and an analog-to-digital converter (ADC). For example, the output circuit 1030 may include a plurality of ADCs respectively arranged between the column decoder and the pixel array 1100 for each column decoder, or an ADC arranged at an output terminal of the column decoder. The timing controller 1010, the row decoder 1020, and the output circuit 1030 may be implemented in one chip or separate chips. A processor for processing an image signal output through the output circuit 1030 may be implemented in a single chip together with the timing controller 1010, the row decoder 1020, and the output circuit 1030.

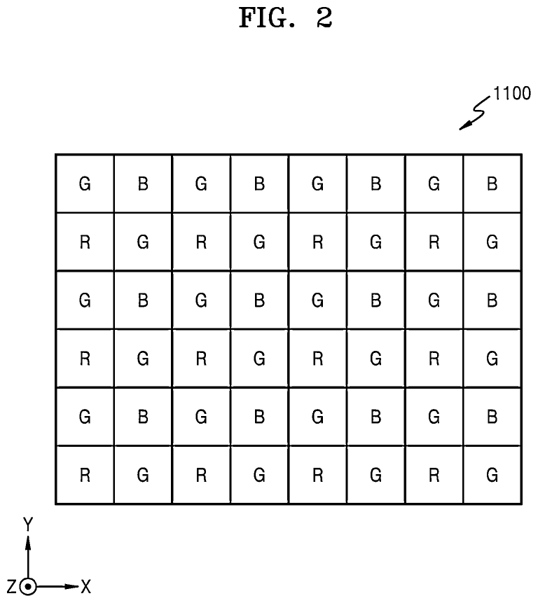

The pixel array 1100 may include a plurality of pixels for sensing light of different wavelengths from each other. The arrangement of the pixels may be implemented in various ways. For example, FIG. 2 illustrates an example of an arrangement of the pixel array 1100 of the image sensor 1000.

FIG. 2 shows the Bayer pattern which is generally adopted in the image sensor 1000. Referring to FIG. 2, one unit pattern may include four quadrant regions, and the first to fourth quadrants may be a blue pixel B, a green pixel G, a red pixel R, and a green pixel G. Such unit pattern may be repeatedly arranged in a two-dimensional (2D) manner in a first direction (X direction) and a second direction (Y direction). In other words, two green pixels G may be arranged in one diagonal direction in a unit pattern of a 2×2 array, and one blue pixel B and one red pixel R may be arranged in another diagonal direction. As for the overall pixel arrangement, a first column in which a plurality of green pixels G and a plurality of blue pixels B are alternately arranged in the first direction, and a second column in which a plurality of red pixels R and a plurality of green pixels G are alternately arranged in the first direction may be repeatedly arranged along a second direction.

The pixel array 1100 may be arranged in various ways other than the Bayer pattern. For example, a CYGM arrangement in which a magenta pixel, a cyan pixel, a yellow pixel, and a green pixel constitute a unit pattern may also be possible. In addition, there may also be an RGBW arrangement in which a green pixel, a red pixel, a blue pixel, and a white pixel constitute a unit pattern. According to an embodiment, a unit pattern may have a 3×2 array form. In addition, the pixels of the pixel array 1100 may be arranged in various ways according to color characteristics of the image sensor 1000. Although the pixel array 1100 of the image sensor 1000 are described as having the Bayer pattern, the operation principle may be applied to a pixel array other than the Bayer pattern.

Hereinafter, for convenience, embodiments are described focusing on a case in which the pixel array 1100 has a Bayer pattern structure.

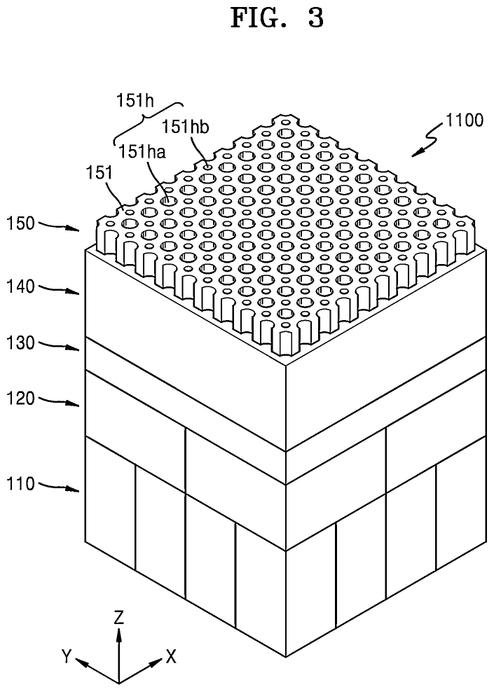

FIG. 3 is a schematic perspective view of a configuration of a pixel array of an image sensor, according to an embodiment. Referring to FIG. 3, the pixel array 1100 may include a substrate 110, a color filter layer 120 arranged on the sensor substrate 110, a planarization layer 130 arranged on the color filter layer 120, a nano optical lens array 140 arranged on the planarization layer 130, and an anti-reflection layer 150 arranged on the nano optical lens array 140. The substrate 110 may be referred to as sensor substrate 110. The color filter layer 120 may be arranged between the substrate 110 and the nano optical lens array 140, and the planarization layer 130 may be arranged between the color filter layer 120 and the nano optical lens array 140. However, the disclosure is not limited thereto, and as such, according to another embodiment, one or more other layers may be provided or and order of the layers may be different. The anti-reflection layer 150 may include a plurality of nano patterns 151h. The plurality of nano patterns 151h may include a plurality of first nano patterns 151ha and a plurality of second nano patterns 151hb. The plurality of first nano patterns 151ha and the plurality of second nano patterns 151hb may be a plurality of nano patterns periodically arranged in a two-dimensional (2D) manner in the anti-reflection layer 150. For example, the plurality of first nano patterns 151ha may be periodically arranged in a two-dimensional (2D) manner in the anti-reflection layer 150, and the plurality of second nano patterns 151hb may be periodically arranged in a two-dimensional (2D) manner in the anti-reflection layer 150. For example, the plurality of first nano patterns 151ha and the plurality of second nano patterns 151hb may be arranged at regular intervals. The arrangement of the plurality of first nano patterns 151ha and the plurality of second nano patterns 151hb may be referred to as being cyclical. However, the disclosure is not limited thereto, and as such, according to another embodiment, the plurality of first nano patterns 151ha and the plurality of second nano patterns 151hb may be arranged in a different manner. The first nano patterns 151ha and the second nano patterns 151hb may penetrate the anti-reflection layer 150 in a third direction (Z direction). The plurality of second nano patterns 151hb may be arranged between the plurality of first nano patterns 151ha. The plurality of first nano patterns 151ha and the plurality of second nano patterns 151hb may have different size, shape, arrangement, etc. from each other. According to another embodiment, the plurality of nano patterns 151h may include a plurality of third nano patterns different from the plurality of first nano patterns 151ha and the plurality of second nano patterns 151hb.

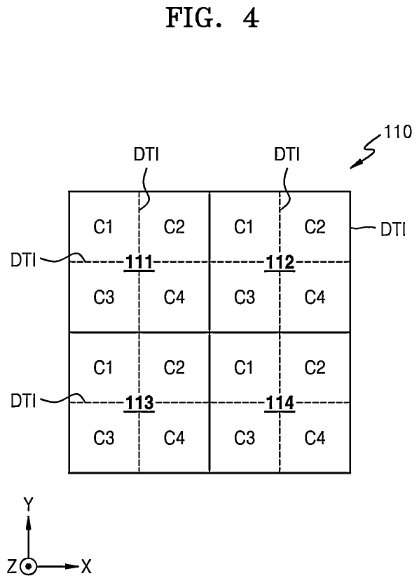

FIG. 4 is a schematic plan view of a configuration of a sensor substrate of the pixel array illustrated in FIG. 3. Referring to FIG. 4, the sensor substrate 110 may include a plurality of pixels sensing incident light. For example, the sensor substrate 110 may include a first pixel 111, a second pixel 112, a third pixel 113, and a fourth pixel 114 which convert incident light into an electrical signal generate an image signal. The first pixel 111, the second pixel 112, the third pixel 113, and the fourth pixel 114 may constitute a unit pixel pattern. The unit pixel pattern may be, for example, a Bayer pattern. For example, the first pixel 111 and the fourth pixel 114 may be green pixels sensing green light, the second pixel 112 may be a blue pixel sensing blue light, and the third pixel 113 may be a red pixel sensing red light.

Although FIGS. 3 and 4 only illustrate one unit pixel pattern including four pixels, the pixel array 1100 may include a plurality of pixel patterns arranged in a 2D manner. For example, a plurality of first pixels 111 and a plurality of second pixels 112 may be alternately arranged in a first direction (X direction), and a plurality of third pixels 113 and a plurality of fourth pixels 114 may be alternately arranged at a different cross-section in a second direction (Y direction) perpendicular to the first direction (X direction). Accordingly, the plurality of first pixels 111, the plurality of second pixels 112, the plurality of third pixels 113, and the plurality of fourth pixels 114 may be arranged in a 2D manner in the first direction and the second direction.

The first to fourth pixels 111, 112, 113, and 114 may each independently include a plurality of light-sensing cells sensing incident light. For examples, the first to fourth pixels 111, 112, 113, and 114 may each include first to fourth light-sensing cells c1, c2, c3, and c4. The first to fourth light-sensing cells c1, c2, c3, and c4 may be arranged in a 2D manner in the first direction (X direction) and the second direction (Y direction). For example, in each of the first to fourth pixels 111, 112, 113, and 114, the first to fourth light-sensing cells c1, c2, c3, and c4 may be arranged in a 2×2 array.

Although FIG. 4 illustrates an example in which the each of the first to fourth pixels 111, 112, 113, and 114 includes four light-sensing cells, four or more independent light-sensing cells may be grouped and arranged in a 2D manner. For example, each of the first to fourth pixels 111, 112, 113, and 114 may include a plurality of independent light-sensing cells grouped and arranged in a 3×3 array or a 4×4 array. Hereinafter, for convenience, embodiments are described focusing on a case in which each of the first to fourth pixels 111, 112, 113, and 114 includes light-sensing cells arranged in a 2×2 array.

According to an embodiment, an automatic focus signal may be obtained from a difference between output signals of adjacent light-sensing cells. For example, an automatic focus signal in the first direction (X direction) may be generated from a difference between an output signal of the first light-sensing cell c1 and an output signal of the second light-sensing cell c2, a difference between an output signal of the third light-sensing cell c3 and an output signal of the fourth light-sensing cell c4, or a difference between the sum of the output signal of the first light-sensing cell c1 and the output signal of the third light-sensing cell c3 and the sum of the output signal of the second light-sensing cell c2 and the output signal of the fourth light-sensing cell c4. In addition, an automatic focus signal in the second direction (Y direction) may be generated from a difference between the output signal of the first light-sensing cell c1 and the output signal of the third light-sensing cell c3, a difference between the output signal of the second light-sensing cell c2 and the output signal of the fourth light-sensing cell c4, or a difference between the sum of the output signal of the first light-sensing cell c1 and the output signal of the second light-sensing cell c2 and the sum of the output signal of the third light-sensing cell c3 and the output signal of the fourth light-sensing cell c4.

A general image signal may be obtained by adding output signals of the first to fourth light-sensing cells c1, c2, c3, and c4. For example, a first green image signal may be generated by adding output signals of the first to fourth light-sensing cells c1, c2, c3, and c4 of the first pixel 111, a blue image signal may be generated by adding output signals of the first to fourth light-sensing cells c1, c2, c3, and c4 of the second pixel 112, a red image signal may be generated by adding output signals of the first to fourth light-sensing cells c1, c2, c3, and c4 of the third pixel 113, and a second green image signal may be generated by adding output signals of the first to fourth light-sensing cells c1, c2, c3, and c4 of the fourth pixel 114.

In addition, each of the first to fourth pixels 111, 112, 113, and 114 may include an isolation film DTI electrically isolating the plurality of light-sensing cells. The isolation film DTI may have, for example, a deep trench isolation structure. A deep trench may be filled with air or an electrically insulating material. The Isolation film DTI may extend in the first direction (X direction) and the second direction (Y direction) to divide each of the first to fourth pixels 111, 112, 113, and 114 into four quadrants. The first to fourth light-sensing cells c1, c2, c3, and c4 of each of the first to fourth pixels 111, 112, 113, and 114 may be separated from each other by the isolation film DTI. The isolation film DTI extending in the first direction (X direction) and the isolation film DTI extending in the second direction (Y direction) may cross each other at the center of each of the first to fourth pixels 111, 112, 113, and 114.

In addition, the isolation film DTI may be arranged in the first direction (X direction) and the second direction (Y direction) between adjacent pixels from among the first to fourth pixels 111, 112, 113, and 114. Accordingly, the first to fourth pixels 111, 112, 113, and 114 may be separated from each other by the isolation film DTI. The isolation film DTI extending in the first direction (X direction) and the isolation film DTI extending in the second direction (Y direction) may cross each other at the center of unit pixel pattern including the first to fourth pixels 111, 112, 113, and 114.

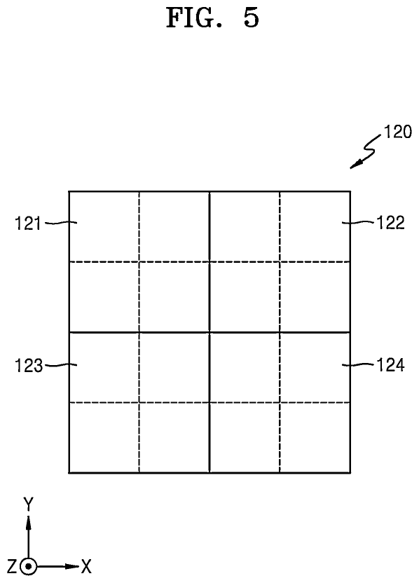

FIG. 5 is a schematic plan view of a configuration of a color filter layer illustrated in FIG. 3. Referring to FIG. 5, the color filter layer 120 may include a plurality of color filters transmitting light of a particular wavelength and absorbing light having other wavelengths. For example, the color filter layer 120 may include a first color filter 121 transmitting light having a first wavelength and absorbing light having other wavelengths, a second color filter 122 transmitting light having a second wavelength different from the first wavelength and absorbing light having other wavelengths, a third color filter 123 transmitting light having a third wavelength different from the first wavelength and the second wavelength and absorbing light having other wavelengths, and a fourth color filter 124 transmitting light having the first wavelength and absorbing light other wavelengths. Although FIG. 5 illustrates only one unit color pattern, a plurality of first color filters 121 and a plurality of second color filters 122 may be alternately arranged in the first direction (X direction), and a plurality of third color filters 123 and a plurality of fourth color filters 124 may be alternately arranged at a different cross-section in the second direction (Y direction) perpendicular to the first direction (X direction).

The first color filter 121 may be arranged to face the corresponding first pixel 111 in the third direction (Z direction), the second color filter 122 may be arranged to face the corresponding second pixel 112 in the third direction (Z direction), the third color filter 123 may be arranged to face the corresponding third pixel 113 in the third direction (Z direction), and the fourth color filter 124 may be arranged to face the corresponding fourth pixel 114 in the third direction (Z direction). Accordingly, the first pixel 111 and the fourth pixel 114 may sense light of the first wavelength transmitted through the corresponding first color filter 121 and fourth color filter 124, respectively. The second pixel 112 may sense light of the second wavelength transmitted through the corresponding second color filter 122. The third pixel 113 may sense light of the third wavelength transmitted through the corresponding third color filter 123. For example, the first color filter 121 and the fourth color filter 124 may be green color filters transmitting green light, the second color filter 122 may be a blue color filter transmitting blue light, and the third color filter 123 may be a red color filter transmitting red light.

The dotted light shown in FIG. 5 represents an isolation film between light-sensing cells of the first to fourth pixels 111, 112, 113, and 114. As illustrated in FIG. 5, the first to fourth color filters 121, 122, 123, and 124 may be arranged to face all light-sensing cells in the respective corresponding first to fourth pixels 111, 112, 113, and 114 in the third direction (Z direction). In other words, the first color filter 121 may cover all light-sensing cells in the first pixel 111, the second color filter 122 may cover all light-sensing cells in the second pixel 112, the third color filter 123 may cover all light-sensing cells in the third pixel 113, and the fourth color filter 124 may cover all light-sensing cells in the fourth pixel 114.

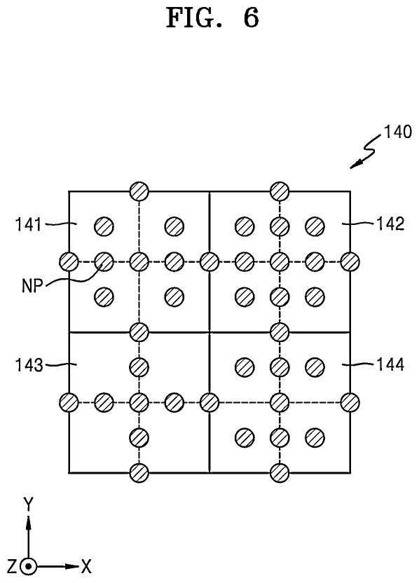

FIG. 6 is a plan view illustrating an example of a configuration of a nano optical lens array illustrated in FIG. 3. Referring to FIG. 6, the nano optical lens array 140 may include a first meta region 141 corresponding to the first pixel 111, a second meta region 142 corresponding to the second pixel 112, a third meta region 143 corresponding to the third pixel 113, and a fourth meta region 144 corresponding to the fourth pixel 114. For example, the first meta region 141 may be arranged to face the first pixel 111 in the third direction (Z direction), the second meta region 142 may be arranged to face the second pixel 112 in the third direction (Z direction), the third meta region 143 may be arranged to face the third pixel 113 in the third direction (Z direction), and the fourth meta region 144 may be arranged to face the fourth pixel 114 in the third direction (Z direction). Although FIG. 6 illustrates only one meta pattern, a plurality of first meta regions 141 and a plurality of second meta regions 142 may be alternately arranged in the first direction (X direction), and a plurality of third meta regions 143 and a plurality of fourth meta regions 144 may be alternately arranged at a different cross-section in the second direction (Y direction) perpendicular to the first direction (X direction).

The first to fourth meta regions 141, 142, 143, and 144 of the nano optical lens array 140 may include a plurality of nano structures NP arranged to condense incident light at the first to fourth pixels 111, 112, 113, and 114, respectively. The plurality of nano structures NP may be arranged to change a phase of light transmitted through the nano optical lens array 140 according to a location of a phase of the nano optical lens array 140. A phase profile of the transmitted light implemented by the nano optical lens array 140 may be determined according to a width (or diameter) and height of each of the nano structures NP and an arrangement cycle (or pitch) and arrangement shape of the plurality of nano structures NP. Moreover, the movement of light transmitted through the nano optical lens array 140 may be determined according to the phase profile of the transmitted light. For example, the plurality of nano structures NP may be arranged to form a phase profile to condense light transmitted through the nano optical lens array 140.

The nano structures NP may have a size smaller than a wavelength of visible light. The nano structures NP may have, for example, a size smaller than a blue wavelength. For example, a cross-sectional width (or diameter) of the nano structure NP may be 400 nm, 300 nm, or 200 nm or less. The cross-sectional width (or diameter) of the nano structure NP may be about 80 nm to about 200 nm. The height of the nano structure NP may be about 500 nm to about 1,500 nm and may be greater than the width of the cross-section. According to an embodiment, the nano structure NP may have a structure in which two or more layers are stacked in the third direction (Z direction).

The nano structure NP may include a material having a relatively high refractive index than peripheral materials and a relatively low absorption rate in the visible light band. For example, the nano structure NP may include c-Si, p-Si, a-Si, III-V group compound semiconductor (GaP, GaN, GaAs, etc.), SiC, TiO₂, SiN₃, ZnS, ZnSe, Si₃N₄, and/or a combination thereof. The periphery of the nano structures NP may be filled with a dielectric material having a relatively lower refractive index than the nano structures NP and a relatively low absorption rate in the visible light band. For example, the periphery of the nano structures NP may be filled with siloxane-based spin on glass (SOG), SiO₂, Si₃N₄, Al₂O₃, air, etc.

The nano structure NP may have a refractive index of 2.0 or greater with respect to light having a wavelength of about 630 nm and have a refractive index of 1.0 or greater and 2.0 or less with respect to light having a wavelength of about 630 nm. In addition, a difference between the refractive index of the nano structures NP and the refractive index of the peripheral materials may be 0.5 or greater. The nano structure NP having a different refractive index from peripheral materials may change a phase of light passing the nano structure NP. This is due to a phase delay caused by the shape dimension of a subwavelength of the nano structure NP, and the degree of phase delay may be determined by detailed shape dimensions, arrangement, etc. of the nano structure NP.

For example, the nano optical lens array 140 may condense light having the first wavelength from among the incident light at the first pixel 111 and the fourth pixel 114, condense light having the second wavelength at the second pixel 112, and condense light having the third wavelength at the third pixel 113. Then, the incident light may be divided by wavelength through the nano optical lens array 140 and be condensed at the first to fourth pixels 111, 112, 113, and 114. To this end, the plurality of nano structures NP may be arranged in different forms in the first to fourth meta regions 141, 142, 143, and 144 of the nano optical lens array 140. Although FIG. 6 illustrates that the nano structures NP have the same diameter, this is only an example, and the diameter of the nano structures NP may vary. In addition, the arrangement of the nano structures NP may vary as well. In an example case in which the incident light is separated sufficiently by the nano optical lens array 140, the color filter layer 120 may be omitted.

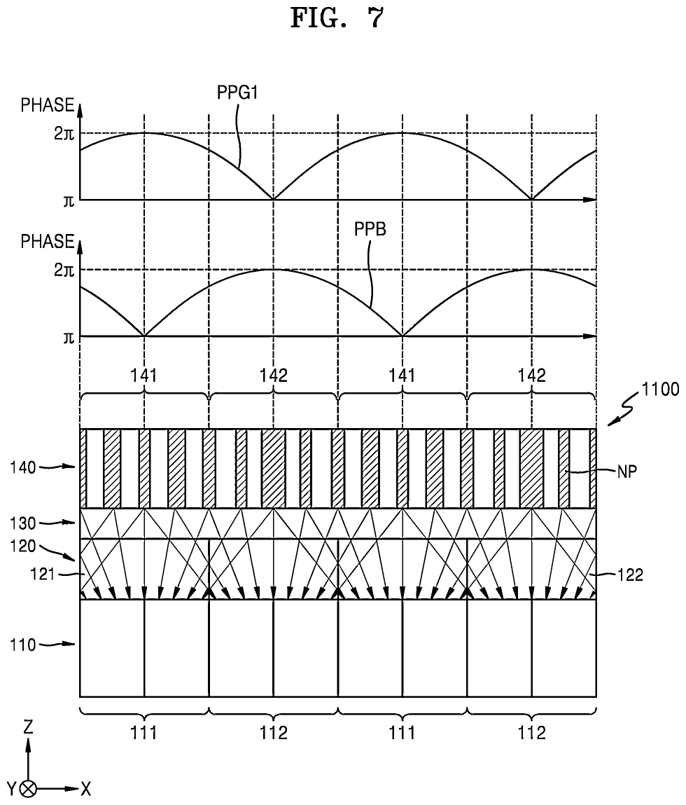

FIG. 7 is a diagram showing phase profiles of green light and blue light, which have passed through a nano optical lens array. Referring to FIG. 7, green light which has passed through the nano optical lens array 140 may have a first green light phase profile PPG1 which is greatest at the center of the first meta region 141 and decreases in a direction away from the center of the first meta region 141. For example, at a position immediately after the green light has passed through the nano optical lens array 140, in other words, on a lower surface of the nano optical lens array 140 or an upper surface of the planarization layer 130, the phase of the green light may be greatest at the center of the first meta region 141 and may gradually decrease concentrically in a direction away from the center of the first meta region 141. In an example case in which the phase of the green light emitted from the center of the first meta region 141 is defined as 2π, the centers of the second meta region 142 and the third meta region 143 may emit light having a phase of about 0.9π to about 1.1π, the center of the fourth meta region 144 may emit light having a phase of 2π, and the contact point between the first meta region 141 and the fourth meta region 144 may emit light having a phase of about 1.1π to about 1.5π. Accordingly, a difference between the phase of the green light transmitted through the center of the first meta region 141 and the phase of the green light transmitted through the center of the second meta region 142 and the third meta region 143 may be about 0.9π to about 1.1π.

Meanwhile, the first green light phase profile PPG1 may not mean that the phase delay amount of light which has passed through the center of the first meta region 141 is the greatest, and in an example case in which the phase of the green light transmitted through the first meta region 141 is defined as 2π, and the phase delay of light which has traveled through other positions has a greater phase value, i.e., greater than 2π, the first green light phase profile PPG1 may be a profile of values obtained by subtracting 2nπ therefrom, i.e., a profile of wrapped phase. In an example case in which the phase of light which has passed through the first meta region 141 is 2π, and the phase of light which has passed through the center of the second meta region 142 is 3π, the phase at the second meta region 142 may be IT which may be obtained by subtracting 2π from 3π(when n=1).

In addition, blue light which has passed through the nano optical lens array 140 may have a blue light phase profile PPB which is greatest at the center of the second meta region 142 and decreases in a direction away from the center of the second meta region 142. For example, at a position immediately after the blue light has passed through the nano optical lens array 140, the phase of the blue light may be greatest at the center of the second meta region 142 and may gradually decrease concentrically in a direction away from the center of the second meta region 142. In an example case in which the phase of the blue light at the center of the second meta region 142 is 2π, the phase at the center of the first meta region 141 and the fourth meta region 144 may be about 0.9π to about 1.1π, and the phase at the center of the third meta region 143 may have a value smaller than the phase at the center of the first meta region 141 and the fourth meta region 144, for example, about 0.5π to about 0.9π.

Then, from among light incident onto the first meta region 141 and light incident onto parts of the peripheral second meta region 142 and third meta region 143, green light may be condensed at the first pixel 111 by the nano optical lens array 140. That is, according to the phase profile of the green light described in relation to FIG. 7, green light which has passed through a first green light condensing region GL1 connecting the centers of the two second meta regions 142 and the two third meta regions 143, which are adjacent to the first meta region 141 by each sharing one side thereof, may be condensed at the first pixel 111.

In addition, from among light incident onto the second meta region 142 and light incident onto parts of the peripheral first meta region 141, third meta region 143, and fourth meta region 144, blue light may be condensed at the second pixel 112 by the nano optical lens array 140. That is, according to the phase profile of the blue light described in relation to FIG. 7, blue light which has passed through a blue light condensing region BL connecting the centers of the four third meta regions 143 which are adjacent to the second meta region 142 by sharing a vertex may be condensed at the second pixel 112.

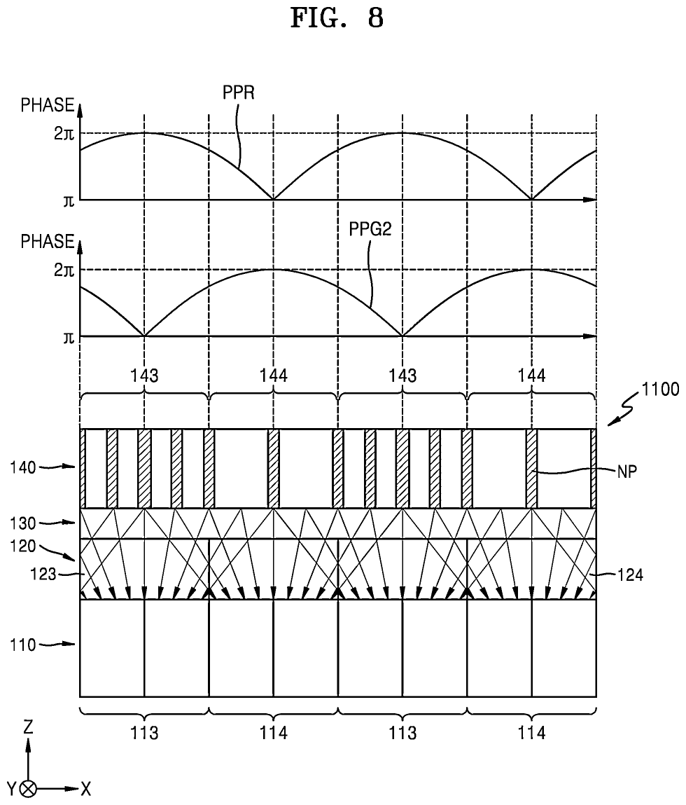

FIG. 8 is a diagram showing phase profiles of red light and green light, which have passed through a nano optical lens array. Referring to FIG. 8, red light which has passed through the nano optical lens array 140 may have a red light phase profile PPR which is greatest at the center of the third meta region 143 and decreases in a direction away from the center of the third meta region 143. For example, at a position immediately after the red light has passed through the nano optical lens array 140, the phase of the red light may be greatest at the center of the third meta region 143 and may gradually decrease concentrically in a direction away from the center of the third meta region 143. In an example case in which the phase of the red light at the center of the third meta region 143 is 2π, the phase at the center of the first meta region 141 and the fourth meta region 144 may be, for example, about 0.9π to about 1.1π, and the phase at the center of the second meta region 142 may have a value smaller than the phase at the center of the first meta region 141 and the fourth meta region 144, for example, about 0.5π to about 0.9π.

In addition, green light which has passed through the nano optical lens array 140 may have a second green light phase profile PPG2 which is greatest at the center of the fourth meta region 144 and decreases in a direction away from the center of the fourth meta region 144. The description about the first green light phase profile PPG1 may be applied to the second green light phase profile PPG2 as well, except that, in the second green light phase profile PPG2, the phase may be the greatest at the center of the fourth meta region 144.

Then, from among light incident onto the third meta region 143 and light incident onto parts of the peripheral first meta region 141, second meta region 142, and fourth meta region 144, red light may be condensed at the third pixel 113 by the nano optical lens array 140. That is, according to the phase profile of the red light described in relation to FIG. 8, red light which has passed through a red light condensing region RL connecting the centers of the four second meta regions 142 which are adjacent to the third meta region 143 by sharing a vertex may be condensed at the third pixel 113.

Moreover, from among light incident onto the fourth meta region 144 and light incident onto parts of the peripheral second meta region 142 and third meta region 143, green light may be condensed at the fourth pixel 114 by the nano optical lens array 140. That is, according to the phase profile of the green light described in relation to FIG. 8, green light which has passed through a second green light condensing region GL2 connecting the centers of the two second meta regions 142 and the two third meta regions 143, which are adjacent to the fourth meta region 144 by each sharing one side thereof, may be condensed at the fourth pixel 114.

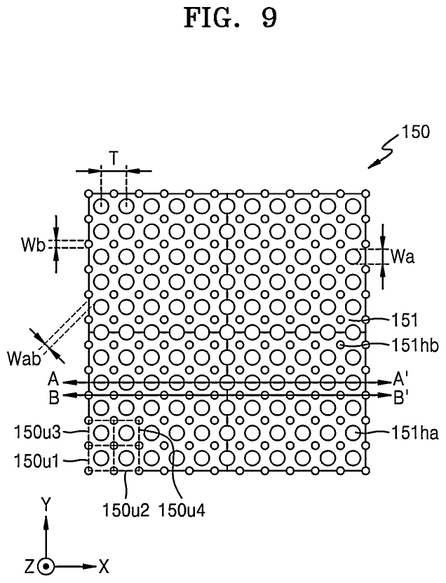

FIG. 9 is a plan view illustrating an example of a configuration of the anti-reflection layer 150. Referring to FIG. 9, the anti-reflection layer 150 may have a structure patterned to include a plurality of nano patterns. For example, the plurality of plurality of nano patterns may be periodically arranged in a 2D manner. For example, the anti-reflection layer 150 may include a dielectric layer 151. For example, the dielectric layer 151 may be transparent with respect to visible light. The anti-reflection layer 150 may further include the first nano patterns 151ha and the second nano patterns 151hb provided in the dielectric layer 151. For example, the first nano patterns 151ha and the second nano patterns 151hb may be arranged to penetrate the dielectric layer 151 in the third direction (Z direction). In some examples, the dielectric layer 151 may include, but is not limited to, at least one of AlO, HfO, SiN, SiO₂, AlOC, AlON, and AlOCN or a combination thereof. In some examples, the dielectric layer 151 may include other inorganic materials having a refractive index of about 1 to 3, in addition to the aforementioned materials. Each of the first nano patterns 151ha and the second nano patterns 151hb may include a dielectric material having a different refractive index than the dielectric layer 151. For example, the first nano patterns 151ha and the second nano patterns 151hb may each be air. In this case, the first nano patterns 151ha and the second nano patterns 151hb may each be a hole formed in the dielectric layer 151. However, the disclosure is not limited thereto, and as such, the first nano patterns 151ha and the second nano patterns 151hb may include a dielectric material filled in the hole of the dielectric layer 151, in addition to the air. For example, the holes corresponding to the first nano patterns 151ha and the second nano patterns 151hb may be filled with a dielectric material different from a material forming the dielectric layer 151. Although FIG. 9 illustrates the cross-sectional shape of the first nano patterns 151ha and the second nano patterns 151hb as circular, the cross-section of the first nano patterns 151ha and/or the second nano patterns 151hb may have various shapes including a circle, ellipse, tetragon, tetragon with round corners, etc.

The anti-reflection layer 150 may include a plurality of unit regions (150u1, 150u2, 150u3, and 150u4). For example, the anti-reflection layer 150 may include a first unit region 150u1, a second unit region 150u2, a third unit region 150u3, and a fourth unit region 150u4 arranged in the first and second rows. The first unit region 150u1 and the second unit region 150u2 may be arranged adjacent to each other in the first row in the first direction (X direction), and the third unit region 150u3 and the fourth unit region 150u4 may be arranged adjacent to each other in the second row in the first direction (X direction). The first row and the second row may be arranged adjacent to each other in the second direction (Y direction).

The second nano patterns 151hb may be arranged in the widest area between the first nano patterns 151ha. For example, the first nano patterns 151ha may be arranged in the first to fourth unit regions 150u1, 150u2, 150u3, and 150u4, and the second nano patterns 151hb may be arranged at the boundaries of the first to fourth unit regions 150u1, 150u2, 150u3, and 150u4. For example, the first nano patterns 151ha may be arranged at a central portion of each of the first to fourth unit regions 150u1, 150u2, 150u3, and 150u4, and the second nano patterns 151hb may be arranged at the boundaries between the first to fourth unit regions 150u1, 150u2, 150u3, and 150u4. The second nano patterns 151hb may be arranged at the boundaries where the first to fourth unit regions 150u1, 150u2, 150u3, and 150u4 meet each other. However, the disclosure is not limited thereto, and as such, according to another embodiment, the second nano patterns 151hb may be arranged at a corner (or vertex) of each of the first to fourth unit regions 150u1, 150u2, 150u3, and 150u4. According to yet another embodiment, the second nano patterns 151hb may be arranged between the first nano patterns 151ha. In an example case in which the plurality of first nano patterns 151ha are arranged in a tetragonal lattice, the second nano patterns 151hb may be arranged at the central portion of four adjacent first nano patterns 151ha forming a unit lattice.

The first nano patterns 151ha and the second nano patterns 151hb may each have dimensions less than the wavelength of visible light. For example, an arrangement cycle T of the first nano patterns 151ha and the second nano patterns 151hb (of the width of the first to fourth unit regions 150u1, 150u2, 150u3, and 150u4) may be about 200 nm to 300 nm, which is less than the wavelength of blue light. For example, the width of the first to fourth unit regions 150u1, 150u2, 150u3, and 150u4 may be about 200 nm to 300 nm, which is less than the wavelength of blue light. For example, the arrangement cycle T of the first nano patterns 151ha and the second nano patterns 151hb may be about 150 nm to about 300 nm or about 200 nm to about 280 nm. However, the disclosure is not limited thereto, and as such, according to another embodiment, the width (or the diameter) of each of the first nano patterns 151ha and the second nano patterns 151hb may be 300 nm or less.

A width Wa of the first nano pattern 151ha may be greater than a width Wb of the second nano pattern 151hb. For example, the width Wa of the first nano pattern 151ha may be at least twice as great as the width Wb of the second nano pattern 151hb. For example, the width Wa of the first nano pattern 151ha may be about 150 nm to about 200 nm or about 160 nm to about 180 nm. In addition, the width Wb of the second nano pattern 151hb may be about 75 nm to about 100 nm or about 80 nm to about 90 nm.

According to an embodiment, a gap Wab between the first nano pattern 151ha and the second nano pattern 151hb may be about 20 nm to about 50 nm. In this regard, the gap Wab between the first nano pattern 151ha and the second nano pattern 151hb may refer to a distance between an edge of the first nano pattern 151ha and edge of the second nano pattern 151hb which are most adjacent to each other.

In each of the first to fourth unit regions 150u1, 150u2, 150u3, and 150u4, a fill factor of the first nano patterns 151ha may be about 30% to about 70%. The aforementioned fill factor may refer to a ratio of a cross-sectional area of the first nano patterns 151ha to a cross-sectional area of each of the first to fourth unit regions 150u1, 150u2, 150u3, and 150u4. However, the disclosure is not limited thereto, and as such, according to another embodiment, in each of the first to fourth unit regions 150u1, 150u2, 150u3, and 150u4, the sum of the fill factor of the first nano patterns 151ha and a fill factor of the second nano patterns 151hb may be about 30% to about 70%.

The arrangement cycle T and the first nano patterns 151ha and the second nano patterns 151hb may be the same in the entire area of the anti-reflection layer 150. In addition, the width (or diameter) Wa of each of the first nano patterns 151ha may be the same in the entire area of the anti-reflection layer 150, and the width (or diameter) Wb of each of the second nano patterns 151hb may be the same in the entire area of the anti-reflection layer 150. The shape of each of the first nano patterns 151ha may be the same in the entire area of the anti-reflection layer 150, and the shape of each of the second nano patterns 151hb may be the same in the entire area of the anti-reflection layer 150. The fill factor of the first nano patterns 151ha in each of the first to fourth unit regions 150u1, 150u2, 150u3, and 150u4 may be the same in the entire area of the anti-reflection layer 150.

The width of the plurality of pixels (111, 112, 113, and 114) of the sensor substrate 110 may be an integer multiple of the arrangement cycle T of the first nano patterns 151ha and the second nano patterns 151hb. Then, in the regions of the anti-reflection layer 150 respectively facing the plurality of pixels (111, 112, 113, and 114) in the third direction (Z direction), the same number of first nano patterns 151ha and the second nano patterns 151hb may be arranged.

The anti-reflection layer 150 arranged on the light incidence surface of the nano optical lens array 140 may have a function of reducing the reflection loss of reflected incident light, caused by the nano optical lens array 140 arranged under the anti-reflection layer 150. To this end, an average refractive index of the anti-reflection layer 150 may be greater than the refractive index of air and less than an average refractive index of the nano optical lens array 140. In an example case in which the refractive index section between the refractive index of air the average refractive index of the nano optical lens array 140 is divided into three sections, the average refractive index of the anti-reflection layer 150 may be in the middle section of the three divided refractive index sections. The average refractive index of the anti-reflection layer 150 may be determined by the refractive index and volume of the dielectric layer 151 and the refractive index and volume of the first nano patterns 151ha and the second nano patterns 151hb. The average refractive index of the nano optical lens array 140 may be determined by a refractive index and volume of the nano structures NP and a refractive index of volume of peripheral materials. The arrangement cycle T of the first nano patterns 151ha and the second nano patterns 151hb and the widths (Wa and Wb) of the first nano patterns 151ha and the second nano patterns 151hb may be determined such that the average refractive index of the anti-reflection layer 150 meets or satisfies the aforementioned conditions.

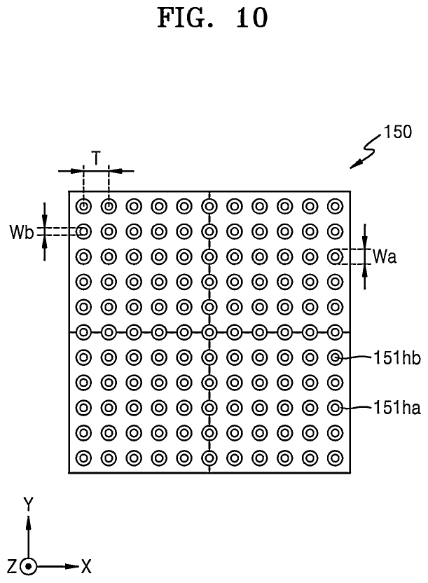

FIG. 10 is a plan view illustrating another example of a configuration of the anti-reflection layer. The description corresponding to the embodiment illustrated in FIG. 10 may focus mainly on the differences between FIG. 9 and FIG. 10. Referring to FIG. 10, the anti-reflection layer 150 may have a structure patterned to include a plurality of nano patterns periodically arranged in a 2D manner. For example, the anti-reflection layer 150 may include the dielectric layer 151, which is transparent with respect to visible light, and the anti-reflection layer 150 may further include the first nano patterns 151ha and the second nano patterns 151hb arranged on the dielectric layer 151. The first nano pattern 151ha may be a structure having a nano post shape arranged on the dielectric layer 151, and the second nano pattern 151hb may be a hole formed in the first nano pattern 151ha. The first nano pattern 151ha may have a columnar or a rod-like shape. However, the disclosure is not limited thereto, and as such, first nano pattern 151ha may have another shape. The first nano pattern 151ha may include a dielectric material having the same refractive index as the dielectric layer 151. However, the disclosure is not limited thereto, and as such, according to another embodiment, the first nano pattern 151ha may include a dielectric material having a different refractive index from the dielectric layer 151. For example, the first nano pattern 151ha may include a material having a refractive index of about 1.0 to about 1.6. However, the disclosure is not limited thereto, and as such, according to another embodiment, the first nano pattern 151ha may include a material having a refractive index of about 1.2 to about 1.5. The first nano pattern 151ha may include, for example, silicon oxide, silicon oxynitride, silicon nitride, aluminum oxide, titanium oxide, and/or hafnium oxide. The second nano pattern 151hb may be air. However, the disclosure is not limited thereto, and as such, according to another embodiment, the second nano pattern 151hb may include a dielectric material filled in the first nano pattern 151ha, in addition to air.

In an example case in which the cross-sectional size of the nano patterns is similar to the wavelength, an effective scattering cross-sectional area may increase significantly due to Mie scattering. In particular, due to the periodic arrangement of the nano patterns, light scattering may be more likely to occur in a wide section between adjacent nano patterns on the anti-reflection layer, and accordingly, there may be an incident angle-wavelength section where a scattering cross-sectional area increases. As Mie scattering is wavelength-dependent, for example, an RGB sensor may have a peak where the reflectivity of blue pixel region, reflectivity of green pixel region, or reflectivity of red pixel region increases significantly. Such phenomenon is difficult to predict in the effective medium theory and may cause a decrease in resolution.

According to an embodiment, as the second nano patterns 151hb are arranged between the first nano patterns 151ha of the anti-reflection layer 150, not only light scatting in a wide section between the nano patterns may be suppressed, but also scattering cross-sectional area in the region having an optical scattering mode may be reduced, and intensive scattering at a particular azimuth (e.g., oblique incidence at an angle of 0° or 90°) may be suppressed. In addition, according to an embodiment, as the anti-reflection layer 150 includes the first nano patterns 151ha, and the second nano patterns 151hb are arranged between or in the first nano patterns 151ha, an average refractive index may be adjusted finely, and a relatively uniform and low reflectivity may be secured in the entire area of the anti-reflection layer 150.

The chief ray angle of incident light on the pixel array 1100 of the image sensor 1000 may vary according to a position on the pixel array 1100. In an example case in which an incidence angle of light vertically incident on the light incidence surface of the pixel array 1100 is 0°, the chief ray angle of incident light incident onto the central portion of the pixel array 1100 is 0°, and the longer a distance from the central portion is, the greater the chief ray angle of incident light incident may be.

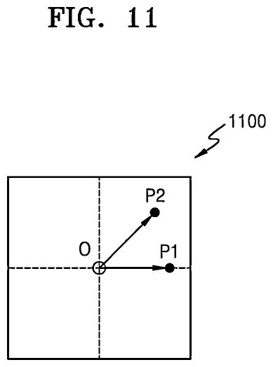

FIG. 11 is a diagram illustrating an example of positions of a central portion and a peripheral portion of the pixel array 1100 at which angles of chief ray of incident light are different from each other. In FIG. 11, the point marked with “0” is the center of the pixel array 1100. The chief ray angle of incident light incident onto the center of the pixel array 1100 may be 0°. Accordingly, a region on the pixel array 1100 where the chief ray angle of incident light is 0° may be defined as the central portion of the pixel array 1100. However, the disclosure is not limited thereto, and as such, according to another embodiment, a partial region around the center of the pixel array 1100 may be defined as the central portion even when the chief ray angle of incident light is not exactly 0° for convenience in manufacturing process. For example, a region on the pixel array 1100 where the chief ray angle of incident light is within 10° may be defined as the central portion of the pixel array 1100. Strictly speaking, a region where the chief ray angle of incident light is greater than 0° or 10° may be defined as the peripheral portion of the pixel array 1100. The central portion and the peripheral portion of the pixel array 1100 may be described as the central portion and the peripheral portion of the image sensor 1000.

At a first position P1 and a second position P2 in the peripheral portion of the pixel array 1100, the chief ray angle of incident light may be greater than 0° or 10°. For example, the chief ray angle may vary according to a distance from a center O of the pixel array 1100. Two different position on the pixel array 1100 may still have the same chief ray angle when they have the same distance from the center O of the pixel array 1100. In addition, the chief ray direction of incident light may vary at the first position P1 and the second position P2 which are different from each other in the azimuth direction. For example, the azimuth of the first position P1 may be 0°, and the azimuth of the second position P2 may be between 0° and 90°, e.g., 45°. The azimuth may be defined as an angle in the counterclockwise direction from a reference line passing the center O of the pixel array 1100 in a direction parallel with the first direction (X direction). The chief ray direction of incident light at the first position P1 may be parallel with the first direction (X direction), and the chief ray direction of incident light at the second position P2 may be a diagonal direction between the first direction (X direction) and the second direction (Y direction).

As such, in the peripheral portion of the pixel array 1100, the chief ray angle and direction may vary according to a position. Accordingly, to secure relatively uniform optical quality such as sensitivity, color separation efficiency, light utilization efficiency, etc. throughout the entire area of the pixel array 1100, the positions of the first to fourth color filters 121, 122, 123, and 124 of the color filter layer 120 and the positions of the first to fourth meta regions 141, 142, 143, and 144 of the nano optical lens array 140 may be adjusted by considering the chief ray angle and direction.

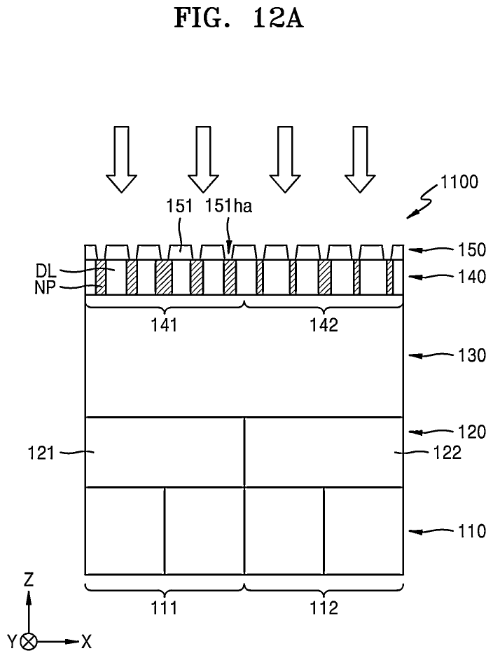

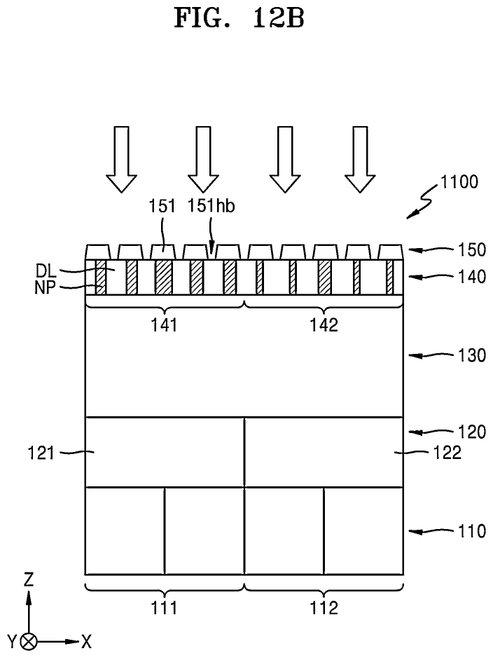

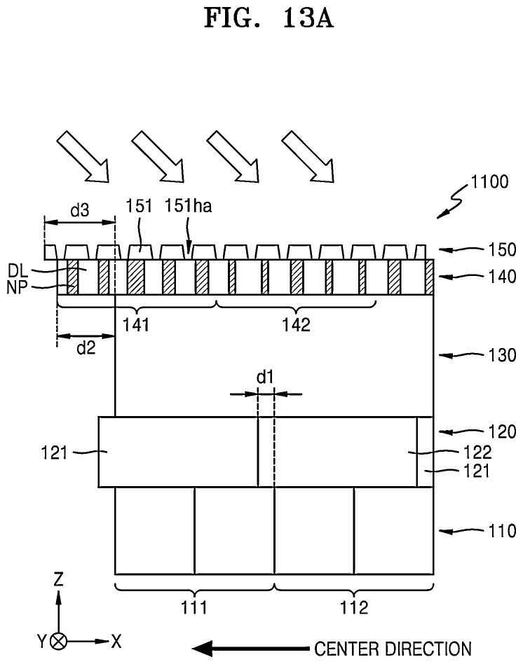

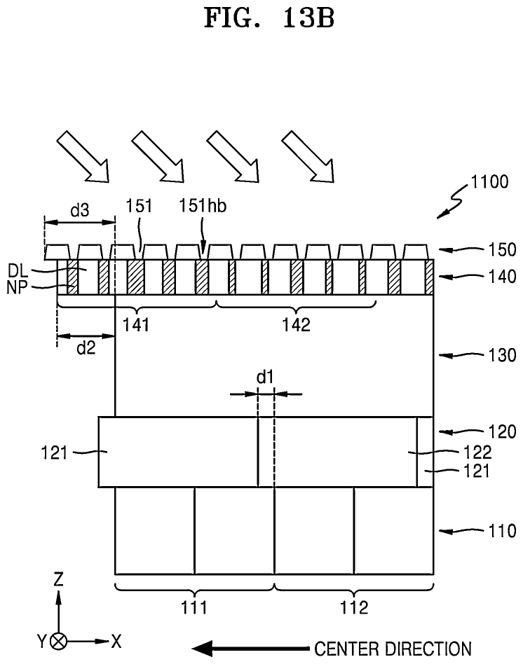

FIGS. 12A and 12B are cross-sectional views schematically showing a cross-sectional structure of the pixel array 1100 at the central portion of the pixel array 1100 according to an embodiment. FIG. 13A is a schematic cross-sectional view taken along line A-A′ of FIG. 9, and FIG. 13B is a schematic cross-sectional view taken along line B-B′ of FIG. 9. Referring to FIGS. 12A and 12B, at the central portion of the pixel array 1100 where incident light is incident vertically, from among the plurality of pixels, the plurality of color filters, and the plurality of meta regions, boundaries of a corresponding pixel, color, filter, and meta region may match each other when seen in the third direction (Z direction). For example, at the central portion of the pixel array 1100, the boundary of the first pixel 111, the boundary of the first color filter 121, and the boundary of the first meta region 141, which correspond to each other may match each other when seen in the third direction (Z direction). In addition, the boundary of the second pixel 112, the boundary of the second color filter 122, and the boundary of the second meta region 142, which correspond to each other may match each other when seen in the third direction (Z direction). Although it is not shown in the cross-sectional views of FIGS. 12A and 12B, the boundary of the third pixel 113, the boundary of the third color filter 123, and the boundary of the third meta region 143 which correspond to each other may match each other when seen in the third direction (Z direction), and the boundary of the fourth pixel 114, the boundary of the fourth color filter 124, and the boundary of the fourth meta region 144 which correspond to each other may match each other when seen in the third direction (Z direction). The reference symbol “DL” in FIGS. 12A and 12B depicts a peripheral material layer filled between the nano structures NP of the nano optical lens array 140.

Referring to FIG. 12A, the plurality of first nano patterns 151ha may be aligned with the nano structures NP arranged under the plurality of first nano patterns 151ha. Referring to FIG. 12B, the plurality of second nano patterns 151hb may not be aligned with the nano structures NP arranged under the plurality of second nano patterns 151hb.

FIGS. 13A and 13B are cross-sectional views schematically showing a cross-sectional structure of the pixel array 1100 at a peripheral portion of the pixel array 1100 according to an embodiment. Referring to FIGS. 13A and 13B, at the peripheral portion of the pixel array 1100 where incident light is incident obliquely, the first to fourth color filters 121, 122, 123, and 124 of the color filter layer 120 and the first to fourth meta regions 141, 142, 143, and 144 of the nano optical lens array 140 may be shifted with respect to the corresponding first to fourth pixels 111, 112, 113, and 114 in a direction of the incident light. Moreover, at the peripheral portion of the pixel array 1100 where the incident light is incident obliquely, the nano patterns 151h (the first nano patterns 151ha and the second nano patterns 151hb) of the anti-reflection layer 150 may be shifted towards the direction of the incident light. In other words, the first to fourth color filters 121, 122, 123, and 124 of the color filter layer 120, the first to fourth meta regions 141, 142, 143, and 144 of the nano optical lens array 140, and the first nano patterns 151ha and the second nano patterns 151hb of the anti-reflection layer 150 may be shifted towards the central portion of the pixel array 1100 with respect to the corresponding first to fourth pixels 111, 112, 113, and 114. For example, the first to fourth color filters 121, 122, 123, and 124 of the color filter layer 120 may be shifted towards the central portion of the pixel array 1100 by a first distance d1 with respect to the corresponding first to fourth pixels 111, 112, 113, and 114, and the first to fourth meta regions 141, 142, 143, and 144 of the nano optical lens array 140 may be shifted towards the central portion of the pixel array 1100 by a second distance d2 with respect to the corresponding first to fourth pixels 111, 112, 113, and 114. In addition, the first nano patterns 151ha and the second nano patterns 151hb of the anti-reflection layer 150 may be shifted towards the central portion of the pixel array 1100 by a third distance d3 with respect to the corresponding first to fourth pixels 111, 112, 113, and 114. The second distance d2, which is a shift distance of the first to fourth meta regions 141, 142, 143, and 144, may be greater than the first distance d1, which is a shift distance of the first to fourth color filters 121, 122, 123, and 124. The third distance d3, which is a shift distance of the first nano patterns 151ha and the second nano patterns 151hb of the anti-reflection layer 150, may be greater than the second distance d2, which is a shift distance of the first to fourth meta regions 141, 142, 143, and 144. Accordingly, at the peripheral portion of the pixel array 1100, the boundaries of corresponding pixel, color filter, meta region, and nano patterns may not match each other in the third direction (Z direction). The longer the distance from the center of the pixel array 1100 is, the greater the shift distance of the first to fourth color filters 121, 122, 123, and 124, the first to fourth meta regions 141, 142, 143, and 144, and the first nano patterns 151ha and the second nano patterns 151hb of the anti-reflection layer 150 may be.

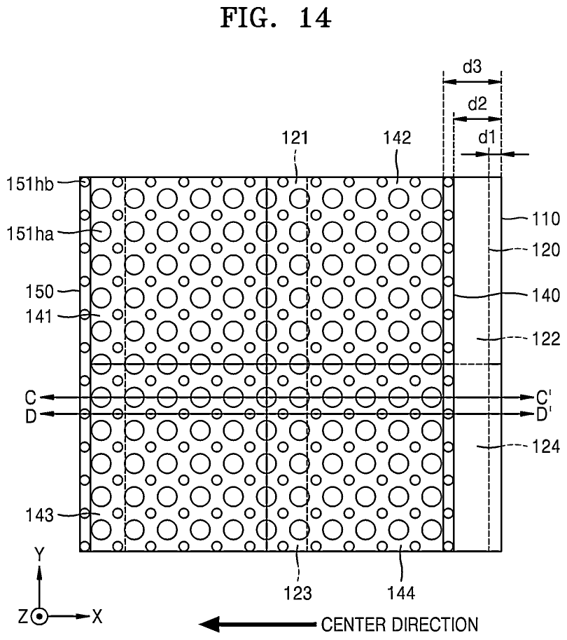

FIG. 14 illustrate an example of relative positions of the sensor substrate 110, the color filter layer 120, the nano optical lens array 140, and the first and second nano patterns 151ha and 151hb of the anti-reflection layer 150 at the first position P1 of the peripheral portion of the pixel array 1100. Referring to FIG. 14, the first to fourth color filters 121, 122, 123, and 124 of the color filter layer 120 may be shifted towards the central portion of the pixel array 1100 by the first distance d1 in the first direction. The first to fourth meta regions 141, 142, 143, and 144 of the nano optical lens array 140 may be shifted towards the central portion of the pixel array 1100 by the second distance d2, which is greater than the first distance d1 in the first direction. In addition, the first and second nano patterns 151ha and 151hb of the anti-reflection layer 150 may be shifted towards the central portion of the pixel array 1100 by the third distance d3 in the first direction.

Referring to FIG. 14 together with FIGS. 13A and 13B, FIG. 13A is a cross-sectional view taken along line C-C′ of FIG. 14, and FIG. 13B is a cross-sectional view taken along line D-D′ of FIG. 14. Referring to FIG. 13A, at the peripheral portion of the pixel array 1100, the plurality of first nano patterns 151ha may not be aligned with the nano structures NP arranged under the plurality of first nano patterns 151ha. Referring to FIG. 13B, the plurality of second nano patterns 151hb may be aligned with the nano structures NP arranged under the plurality of second nano patterns 151hb. Although FIG. 13A illustrates that at the peripheral portion of the pixel array 1100, the plurality of first nano patterns 151ha are not aligned with the nano structures NP arranged under the plurality of first nano patterns 151ha, the plurality of first nano patterns 151ha may be aligned with the nano structures NP at the peripheral portion of the pixel array 1100. In addition, although FIG. 13B illustrates that at the peripheral portion of the pixel array 1100, the plurality of second nano patterns 151hb are aligned with the nano structures NP arranged under the plurality of second nano patterns 151hb, the plurality of second nano patterns 151hb may not be aligned with the nano structures NP at the peripheral portion of the pixel array 1100.

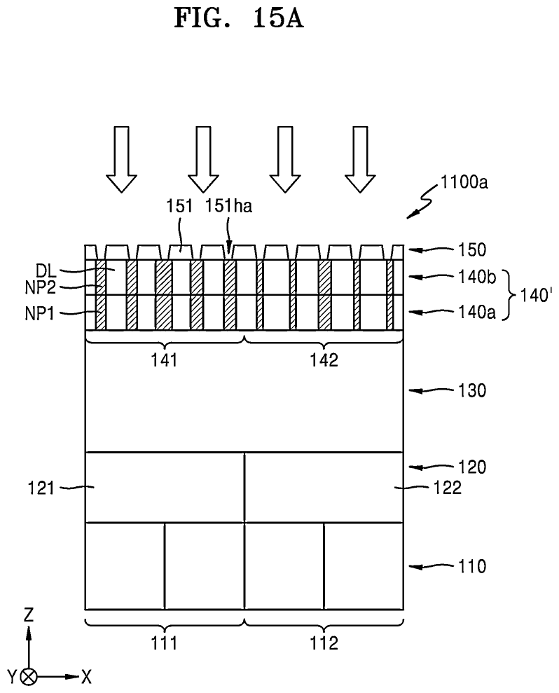

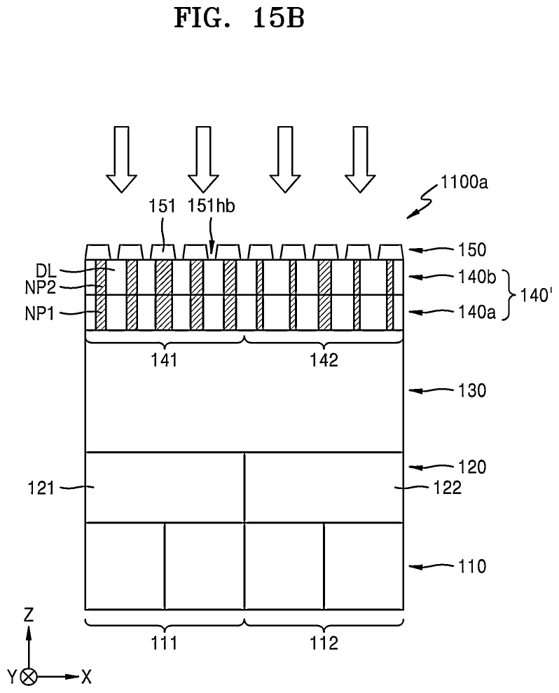

FIGS. 15A and 15B are cross-sectional views schematically showing a cross-sectional structure of a pixel array 1100a at a central portion of the pixel array 1100a, according to another embodiment. Referring to FIGS. 15A and 15B, the pixel array 1100a according to another embodiment may include the sensor substrate 110, the color filter layer 120, the planarization layer 130, a nano optical lens array 140′, and the anti-reflection layer 150. The nano optical lens array 140′ may have a multi-layer structure. For example, the nano optical lens array 140′ may include a first layer meta region 140a and a second layer meta region 140b arranged thereon. The first layer meta region 140a may include a plurality of first nano structures NP1. The second layer meta region 140b may include a plurality of second nano structures NP2. From the nano structure's perspective, the nano optical lens array 140′ may include a two-layered nano structure. The plurality of first nano structures NP1 and the plurality of second nano structures NP2 may have the same arrangement or may different arrangements from each other in consideration of the color separation efficiency and sensitivity according to a chief ray angle. Referring to FIG. 15A, the plurality of first nano patterns 151ha may be aligned with the second nano structures NP2 arranged under the plurality of first nano patterns 151ha. Referring to FIG. 15B, the plurality of second nano patterns 151hb may not be aligned with the second nano structures NP2 arranged under the plurality of second nano patterns 151hb. The rest of the structure of the pixel array 1100a illustrated in FIGS. 15A and 15B may be the same as the structure of the pixel array 1100 described above.

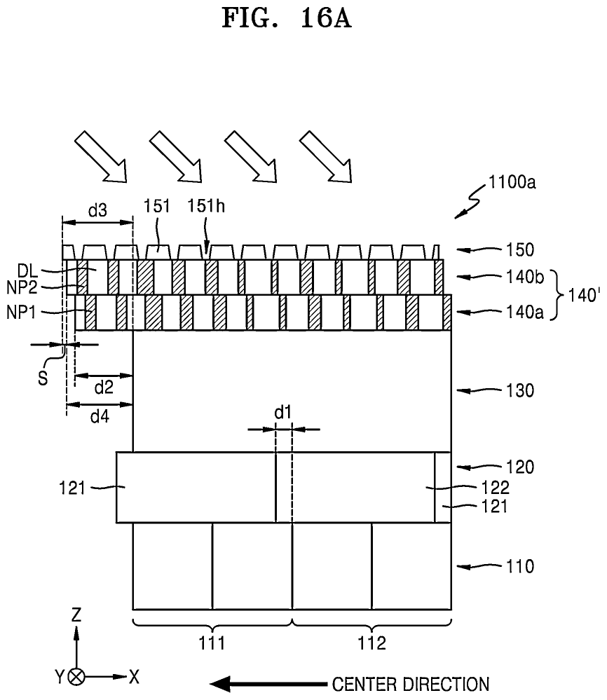

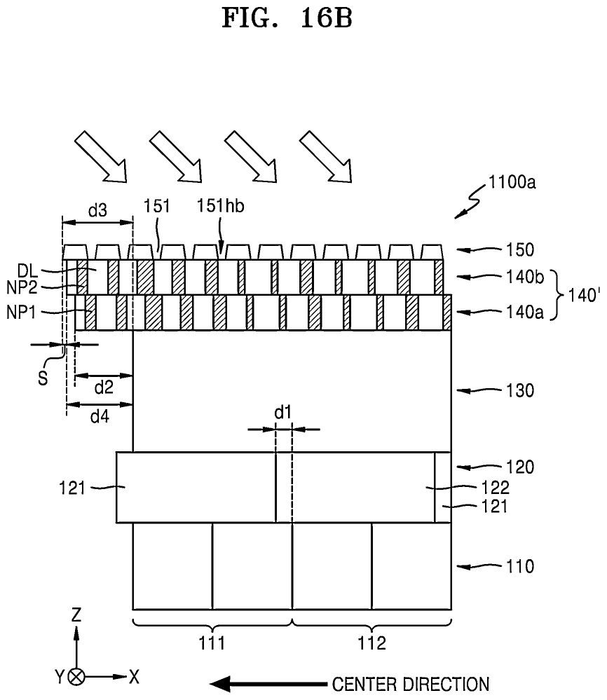

FIGS. 16A and 16B are cross-sectional views schematically showing a cross-sectional structure of the pixel array 1100a at a peripheral portion of the pixel array 1100a, according to another embodiment. Referring to FIGS. 16A and 16B, the shift distance of the first to fourth color filters 121, 122, 123, and 124 of the color filter layer 120 may be the same as described above. The shift distance of the first layer meta region 140a may be identical to the shift distance of the first to fourth meta regions 141, 142, 143, and 144 described above. The second layer meta region 140b may be shifted towards the central portion of the pixel array 1100 by a fourth distance d4, which is greater than the second distance d2. The shift distance of the anti-reflection layer 150 may be the same as described above.

Referring to FIG. 16A, the plurality of first nano patterns 151ha may not be aligned with the second nano structures NP2 arranged under the plurality of first nano patterns 151ha. Referring to FIG. 16B, the plurality of second nano patterns 151hb may be aligned with the second nano structures NP2 arranged under the plurality of second nano patterns 151hb. Although FIG. 16A illustrates that at the peripheral portion of the pixel array 1100, the plurality of first nano patterns 151ha are not aligned with the second nano structures NP2 arranged under the plurality of first nano patterns 151ha, the plurality of first nano patterns 151ha may be aligned with the second nano structures NP2 at the peripheral portion of the pixel array 1100. In addition, although FIG. 16B illustrates that at the peripheral portion of the pixel array 1100, the plurality of second nano patterns 151hb are aligned with the second nano structures NP2 arranged under the plurality of second nano patterns 151hb, the plurality of second nano patterns 151hb may not be aligned with the second nano structures NP2 at the peripheral portion of the pixel array 1100.

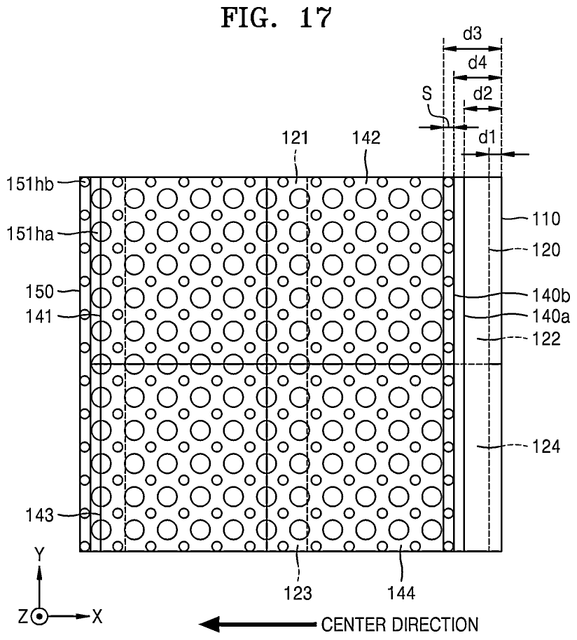

FIG. 17 illustrate an example of relative positions of the sensor substrate 110, the color filter layer 120, the first and second layer meta regions 140a and 140b, and the first and second nano patterns 151ha and 151hb of the anti-reflection layer 150 at the first position P1 of the peripheral portion of the pixel array 1100a. Referring to FIG. 17, the first to fourth color filters 121, 122, 123, and 124 of the color filter layer 120 may be shifted towards the central portion of the pixel array 1100a by the first distance d1 in the first direction. The first layer meta region 140a may be shifted towards the central portion of the pixel array 1100a by the second distance d2, which is greater than the first distance d1 in the first direction. The second layer meta region 140b may be shifted towards the central portion of the pixel array 1100a by the fourth distance d4, which is greater than the second distance d2 in the first direction. In addition, the first and second nano patterns 151ha and 151hb of the anti-reflection layer 150 may be shifted towards the central portion of the pixel array 1100a by the third distance d3, which is greater than the fourth distance d4 in the first direction. A shift distance S of the first nano patterns 151ha and the second nano patterns 151hb of the anti-reflection layer 150 with respect to the second layer meta region 140b may be determined according to the thickness of the anti-reflection layer 150, the refractive index of the anti-reflection layer 150, and/or the chief ray angle of incident light.

The shift distance of each of the anti-reflection layer 150, the second layer meta region 140b, the first layer meta region 140a, the planarization layer 130, and the color filter layer 120 with respect to a corresponding pixel may be determined according to Formula 1:

$$total {shif t}_{j} = {\sum }_{i = j}^{s} {κ}_{i} \cdot {shift}_{i} = {κ}_{i} {\sum }_{i = j}^{s} {L}_{i} \cdot \frac{\frac{1}{{n}_{i}} \cdot sin CRA}{\sqrt{1 - {\{ \frac{1}{{n}_{i}} \cdot sin CRA \}}^{2}}} , ( j = 1 , 2 , 3 )$$

wherein CRA means a chief ray angle of incident light. In addition, Li represents a thickness of each layer, and nᵢ represents a refractive index, wherein when i=1, it represents the anti-reflection layer 150, when i=2, it represents the second layer meta region 140b, when i=3, it represents the first layer meta region 140a, when i=4, it represents planarization layer 130, and when i=5, it represents the color filter layer 120. Moreover, total shift₁ represents a shift distance of the anti-reflection layer 150 with respect to a corresponding pixel, total shift₂ represents a shift distance of the second layer meta region 140b with respect to a corresponding pixel, and total shifts represents a shift distance of the first layer meta region 140a with respect to a corresponding pixel. shift₁ represents a shift distance of the anti-reflection layer 150 with respect to the second layer meta region 140b, shift₂ represents a shift distance of the second layer meta region 140b with respect to the first layer meta region 140a, shift₃ represents a shift distance of the first layer meta region 140a with respect to the planarization layer 130, shift₄ represents a shift distance of the planarization layer 130 with respect to the color filter layer 120, and shift₅ represents a shift distance of the color filter layer 120 with respect to a corresponding pixel. κᵢ is a proportional constant, and when i=1, −2≤κ₁<1, when i=2 or 3, 0<κᵢ<1, and when i=4 or 5, κᵢ=1.

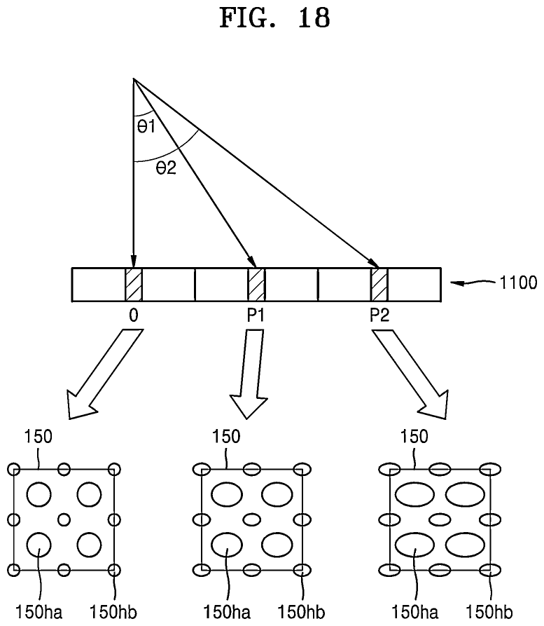

FIG. 18 is a diagram illustrating changes in shapes of the nano patterns of the anti-reflection layer at different positions on the pixel array, according to an embodiment. Referring to FIG. 18, the point marked with “0” is located at the center of the pixel array 1100, and thus the chief ray angle of incident light is 0°. P1 is located at a position where the chief ray angle of incident light is θ1, and P2 is located at a position where the chief ray angle of incident light is θ2.

In an example case in which the chief ray angle of incident light changes, the cross-sectional shape of the first nano patterns 151ha may change as well. For example, at the point “0”, the cross-sectional shape of the first nano patterns 151ha may be circular, and at the point P1 or P2, the cross-sectional shape of the first nano patterns 151ha may be elliptical. In an example case in which the chief ray angle of incident light changes, the cross-sectional shape of the first nano patterns 151ha may gradually change. For example, at P21, the cross-section of the first nano patterns 151ha may have an elliptical shape having a first eccentricity, and at P2, the cross-section of the first nano patterns 151ha may have an elliptical shape having a second eccentricity greater than the first eccentricity. In an example case in which the chief ray angle of incident light changes, the cross-sectional shape of the second nano patterns 151hb may change as well.

Moreover, in an example case in which the chief ray angle of incident light changes, the width of the first nano patterns 151ha may change accordingly. In an example case in which the chief ray angle of incident light changes, the width of the first nano patterns 151ha may gradually change. For example, at “0”, the first nano pattern 151ha may have a first width, at P1, the first nano pattern 151ha may have a second width greater than the first width, and at P2, the first nano pattern 151ha may have a third width greater than the second width. In an example case in which the chief ray angle of incident light changes, the width of the second nano patterns 151hb may change accordingly.

The image sensor 1000 according to an embodiment may minimize the reflection loss of light to further improve the light utilization efficiency of the image sensor 1000 and may maintain uniform optical characteristics over the entire area of the image sensor 1000 or the entire area of the pixel array 1100. In addition, in the image sensor 1000 according to an embodiment, the nano optical lens array 140 may color-separate incident light instead of absorbing or reflecting the incident light and condense the color-separated light at each of the plurality of pixels such that the image sensor 1000 may have improved light utilization efficiency and minimized resolution decrease. Accordingly, as it is possible to reduce the size of one pixel or the size of independent light-sensing cells in a pixel of the image sensor 1000, the image sensor 1000 may have a higher resolution. The image sensor 1000 according to an embodiment may constitute a camera module along with a module lens having various functions and may be used in various electronic devices.

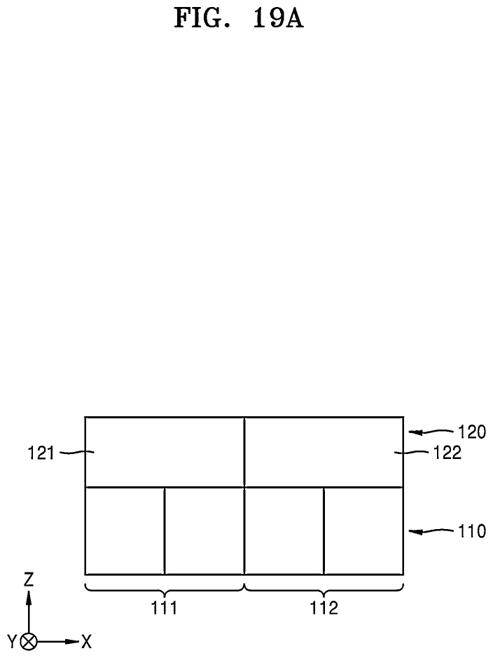

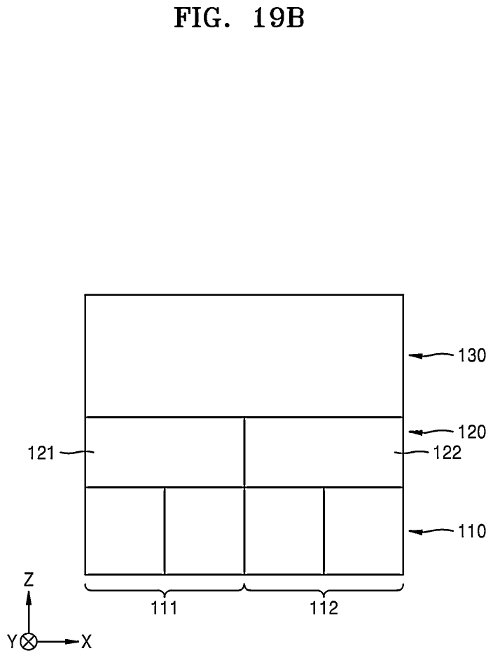

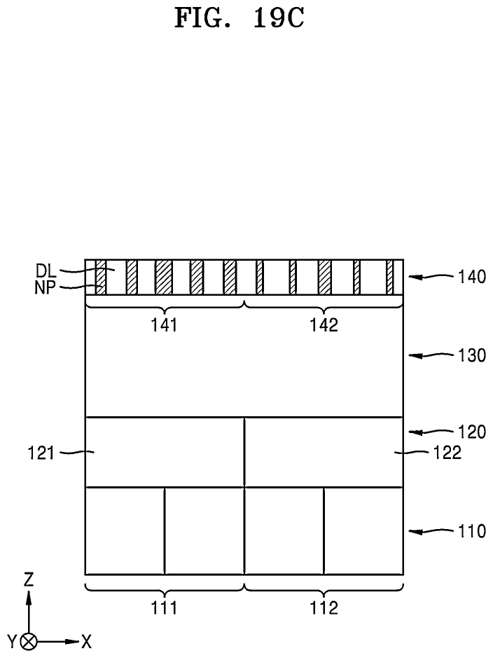

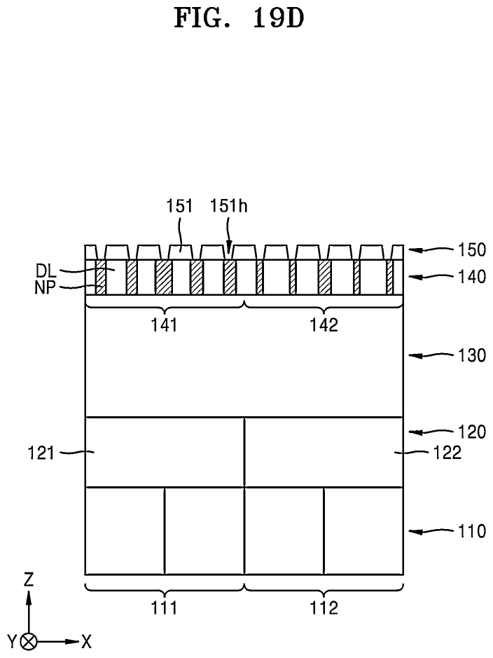

FIGS. 19A to 19D are cross-sectional views illustrating a manufacturing method of the image sensor 1000, according to an embodiment. Referring to FIG. 19A, the color filter layer 120 may be arranged on the sensor substrate 110. Referring to FIG. 19B, the planarization layer 130 may be arranged on the color filter layer 120. Referring to FIG. 19C, the nano optical lens array 140 may be arranged on the planarization layer 130. Referring to FIG. 19D, the anti-reflection layer 150 including the plurality of nano patterns 151h (the first nano patterns 151ha and the second nano patterns 151hb) may be arranged on the nano optical lens array 140.

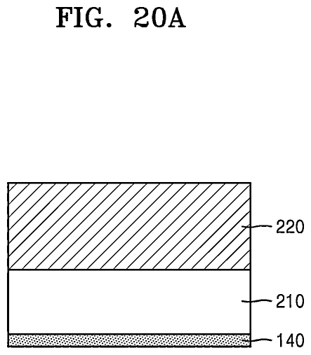

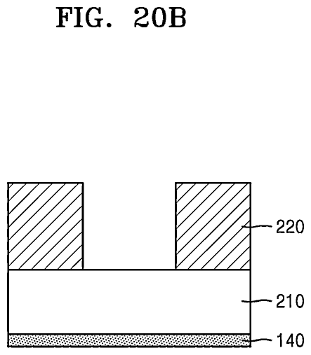

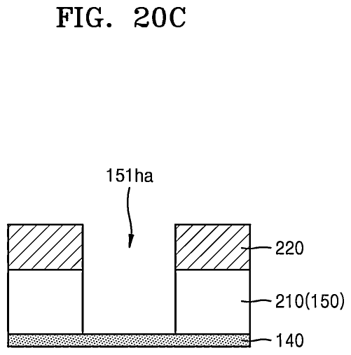

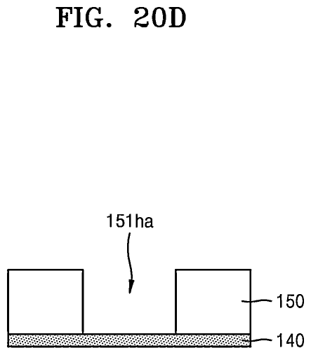

FIGS. 20A to 20D are diagrams illustrating a manufacturing method of the first nano patterns 151ha. A dielectric layer 210 may be similar to the dielectric layer 151 described above. Referring to FIG. 20A, the dielectric layer 210 may be arranged on the nano optical lens array 140, and a photoresist layer 220 may be arranged on the dielectric layer 210. Referring to FIG. 20B, the photoresist layer 220 may be selectively exposed and patterned by using a photomask to partially expose an upper surface of the dielectric layer 210. Referring to FIG. 20C, the exposed portion of the dielectric layer 210 may be etched by using the photoresist layer 220 as an etching mask to manufacture the anti-reflection layer 150 including the plurality of first nano patterns 151ha. Referring to FIG. 20D, the photoresist layer 220 on the anti-reflection layer 150 may be removed.

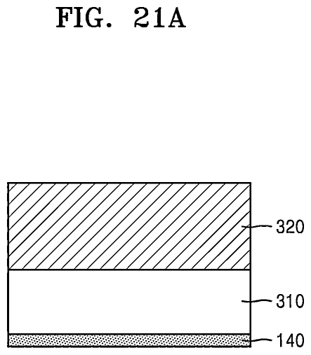

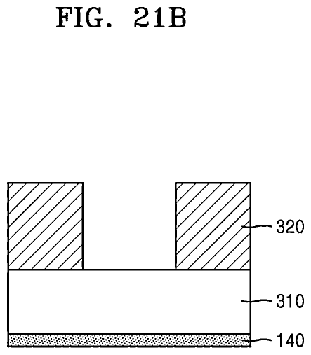

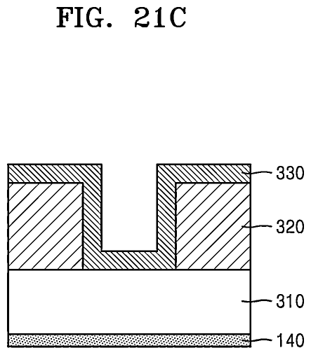

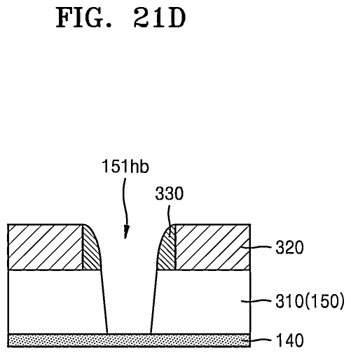

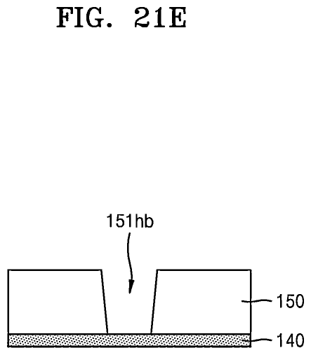

FIGS. 21A to 21E are diagrams illustrating a manufacturing method of the second nano patterns 151hb. A dielectric layer 310 may be similar to the dielectric layer 151 described above. Referring to FIG. 21A, the dielectric layer 310 may be arranged on the nano optical lens array 140, and a photoresist layer 320 may be arranged on the dielectric layer 310. Referring to FIG. 21B, the photoresist layer 320 may be selectively exposed and patterned by using a photomask to partially expose an upper surface of the dielectric layer 310. Referring to FIG. 21C, a spacer layer 330 may be arranged on the photoresist layer 320 to decrease the width of an opening of the photoresist layer 320. Referring to FIG. 21D, the exposed portion of the dielectric layer 310 may be etched by using the photoresist layer 320 and the spacer layer 330 as an etching mask to manufacture the anti-reflection layer 150 including the plurality of second nano patterns 151hb. Referring to FIG. 21E, the photoresist layer 320 may be removed to form the anti-reflection layer 150 including the plurality of second nano patterns 151hb having a width less than the width of the plurality of first nano patterns 151ha.

According to another embodiment, the manufacturing method of the image sensor 1000 may include forming the plurality of first nano patterns 151ha in the dielectric layer 210 (or the dielectric layer 310), and then arranging the spacer layer 330 in the etching process of the plurality of second nano patterns 151hb as illustrated in FIGS. 21A to 21E to form the plurality of second nano pattern 151hb having a width less than the width of the plurality of first nano patterns 151ha in the anti-reflection layer 150. The image sensor 1000 manufactured by the manufacturing method according to an embodiment may minimize the reflection loss of light by the anti-reflection layer 150 having the plurality of first nano patterns 151ha and the plurality of second nano patterns 151hb to more improve the light utilization efficiency of the image sensor 1000. In addition, the image sensor 1000 capable of maintaining uniform optical characteristics throughout the entire area of the image sensor 1000 or the entire area of the pixel array 1100 may be manufacture by the manufacturing method according to an embodiment. Accordingly, as it is possible to reduce the size of one pixel or the size of independent light-sensing cells in a pixel of the image sensor 1000, the image sensor 1000 may have a higher resolution.

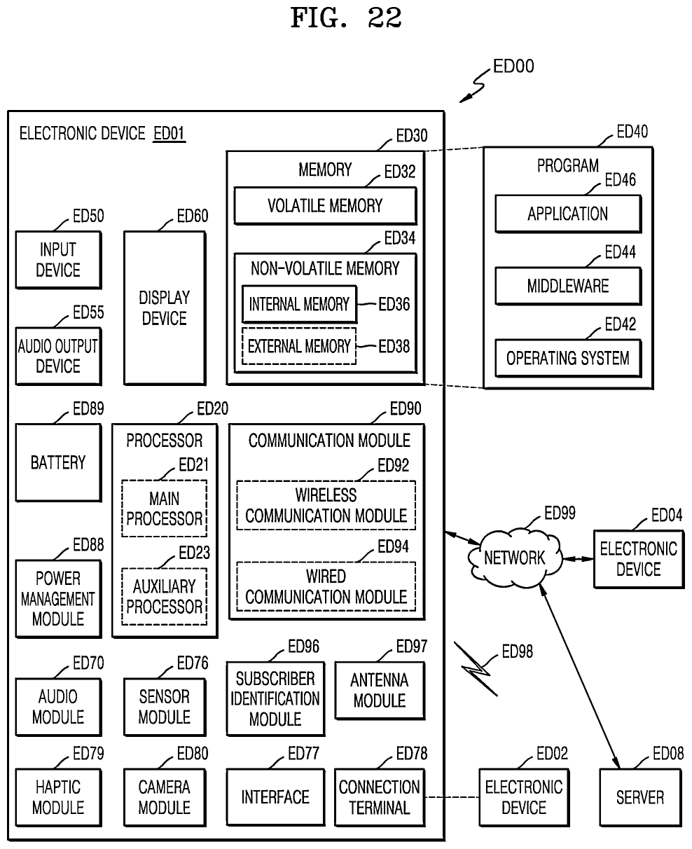

FIG. 22 is a block diagram illustrating an example of an electronic device ED01 including the image sensor 1000. Referring to FIG. 22, in a network environment ED00, the electronic device ED01 may communicate with another electronic device ED02 through a first network ED98 (e.g., short-range wireless communication network, etc.), or communicate with another electronic device ED04 and/or a server ED08 through a second network ED99 (e.g., long-range wireless communication network, etc.) The electronic device ED01 may communicate with the electronic device ED04 through the server ED08. The electronic device ED01 may include a processor ED20, a memory ED30, an input device ED50, an audio output device ED55, a display device ED60, an audio module ED70, a sensor module ED76, an interface ED77, a haptic module ED79, a camera module ED80, a power management module ED88, a battery ED89, a communication module ED90, a subscriber identification module ED96, and/or an antenna module ED97. In the electronic device ED01, some (the display device ED60, and the like) of constituent elements may be omitted or other constituent elements may be added. Some of the constituent elements may be implemented by one integrated circuit. For example, the sensor module ED76 (a fingerprint sensor, an iris sensor, an illuminance sensor, and the like) may be implemented by being embedded in the display device ED60 (a display, and the like).

The processor ED20 may control one or a plurality of other constituent elements (hardware and software constituent elements, and the like) of the electronic device ED01 connected to the processor ED20 by executing software (a program ED40, and the like), and perform various data processing or calculations. As part of the data processing or calculations, the processor ED20 may load, in a volatile memory ED32, commands and/or data received from other constituent elements (the sensor module ED76, the communication module ED90, and the like), process the command and/or data stored in the volatile memory ED32, and store result data in a non-volatile memory ED34. The processor ED20 may include a main processor ED21 (a central processing unit, an application processor, and the like) and an auxiliary processor ED23 (a graphics processing unit, an image signal processor, a sensor hub processor, a communication processor, and the like) that is operable independently of or together with the main processor ED21. The auxiliary processor ED23 may use less power than the main processor ED21 and may perform a specialized function.

Instead of the main processor ED21 when the main processor ED21 is in an inactive state (sleep state), or with the main processor ED21 when the main processor ED21 is in an active state (application execution state), the auxiliary processor ED23 may control functions and/or states related to some constituent elements (the display device ED60, the sensor module ED76, the communication module ED90, and the like) of the constituent elements of the electronic device ED01. The auxiliary processor ED23 (an image signal processor, a communication processor, and the like) may be implemented as a part of functionally related other constituent elements (the camera module ED80, the communication module ED90, and the like).

The memory ED30 may store various data needed by the constituent elements (the processor ED20, the sensor module ED76, and the like) of the electronic device ED01. The data may include, for example, software (the program ED40, and the like) and input data and/or output data about commands related thereto. The memory ED30 may include the volatile memory ED32 and/or the non-volatile memory ED34.

The program ED40 may be stored in the memory ED30 as software, and may include an operating system ED42, middleware ED44, and/or an application ED46.

The input device ED50 may receive commands and/or data to be used for constituent elements (the processor ED20, and the like) of the electronic device ED01, from the outside (a user, and the like) of the electronic device ED01. The input device ED50 may include a microphone, a mouse, a keyboard, and/or a digital pen (a stylus pen, and the like).

The audio output device ED55 may output an audio signal to the outside of the electronic device ED01. The audio output device ED55 may include a speaker and/or a receiver. The speaker may be used for general purposes such as multimedia playback or recording playback, and the receiver can be used to receive incoming calls. The receiver may be implemented by being coupled as a part of the speaker or by an independent separate device.

The display device ED60 may visually provide information to the outside of the electronic device ED01. The display device ED60 may include a display, a hologram device, or a projector, and a control circuit to control a corresponding device. The display device ED60 may include a touch circuitry set to detect a touch and/or a sensor circuit (a pressure sensor, and the like) set to measure the strength of a force generated by the touch.

The audio module ED70 may convert sound into electrical signals or reversely electrical signals into sound. The audio module ED70 may obtain sound through the input device ED50, or output sound through a speaker and/or a headphone of another electronic device (the electronic device ED02, and the like) connected to the audio output device ED55 and/or the electronic device ED01 in a wired or wireless manner.

The sensor module ED76 may detect an operation state (power, temperature, and the like) of the electronic device ED01, or an external environment state (a user state, and the like), and generate an electrical signal and/or a data value corresponding to a detected state. The sensor module ED76 may include a gesture sensor, a gyro sensor, a barometric pressure sensor, a magnetic sensor, an acceleration sensor, a grip sensor, a proximity sensor, a color sensor, an IR sensor, a biometric sensor, a temperature sensor, a humidity sensor, and/or an illuminance sensor.

The interface ED77 may support one or a plurality of specified protocols used for the electronic device ED01 to be connected to another electronic device (the electronic device ED02, and the like) in a wired or wireless manner. The interface ED77 may include a high definition multimedia interface (HDMI), a universal serial bus (USB) interface, an SD card interface, and/or an audio interface.

A connection terminal ED78 may include a connector for the electronic device ED01 to be physically connected to another electronic device (the electronic device ED02, and the like). The connection terminal ED78 may include an HDMI connector, a USB connector, an SD card connector, and/or an audio connector (a headphone connector, and the like).

The haptic module ED79 may convert electrical signals into mechanical stimuli (vibrations, movements, and the like) or electrical stimuli that are perceivable by a user through tactile or motor sensations. The haptic module ED79 may include a motor, a piezoelectric device, and/or an electrical stimulation device.

The camera module ED80 may capture a still image and a video. The camera module ED80 may include a lens assembly including one or a plurality of lenses, the image sensor 1000 of FIG. 1, image signal processors, and/or flashes. The lens assembly included in the camera module ED80 may collect light emitted from a subject for image capturing.

The power management module ED88 may manage power supplied to the electronic device ED01. The power management module ED88 may be implemented as a part of a power management integrated circuit (PMIC).

The battery ED89 may supply power to the constituent elements of the electronic device ED01. The battery ED89 may include non-rechargeable primary cells, rechargeable secondary cells, and/or fuel cells.

The communication module ED90 may establish a wired communication channel and/or a wireless communication channel between the electronic device ED01 and another electronic device (the electronic device ED02, the electronic device ED04, the server ED08, and the like), and support a communication through an established communication channel. The communication module ED90 may be operated independent of the processor ED20 (the application processor, and the like), and may include one or a plurality of communication processors supporting a wired communication and/or a wireless communication. The communication module ED90 may include a wireless communication module ED92 (a cellular communication module, a short-range wireless communication module, a global navigation satellite system (GNSS) communication module, and the like), and/or a wired communication module ED94 (a local area network (LAN) communication module, a power line communication module, and the like). Among the above communication modules, a corresponding communication module may communicate with another electronic device through the first network ED98 (a short-range communication network such as Bluetooth, WiFi Direct, or infrared data association (IrDA)) or the second network ED99 (a long-range communication network such as a cellular network, the Internet, or a computer network (LAN, WAN, and the like)). These various types of communication modules may be integrated into one constituent element (a single chip, and the like), or may be implemented as a plurality of separate constituent elements (multiple chips). The wireless communication module ED92 may verify and authenticate the electronic device ED01 in a communication network such as the first network ED98 and/or the second network ED99 by using subscriber information (an international mobile subscriber identifier (IMSI), and the like) stored in the subscriber identification module ED96.

The antenna module ED97 may transmit signals and/or power to the outside (another electronic device, and the like) or receive signals and/or power from the outside. An antenna may include an emitter formed in a conductive pattern on a substrate (a printed circuit board (PCB), and the like). The antenna module ED97 may include one or a plurality of antennas. In an example case in which the antenna module ED97 includes a plurality of antennas, the communication module ED90 may select, from among the antennas, an appropriate antenna for a communication method used in a communication network such as the first network ED98 and/or the second network ED99. Signals and/or power may be transmitted or received between the communication module ED90 and another electronic device through the selected antenna. Other parts (an RFIC, and the like) than the antenna may be included as a part of the antenna module ED97.

Some of the constituent elements may be connected to each other through a communication method between peripheral devices (a bus, general purpose input and output (GPIO), a serial peripheral interface (SPI), a mobile industry processor interface (MIPI), and the like) and may mutually exchange signals (commands, data, and the like).

The command or data may be transmitted or received between the electronic device ED01 and the external electronic device ED04 through the server ED08 connected to the second network ED99. The electronic devices ED02 and ED04 may be of a type that is the same as or different from the electronic device ED01. All or a part of operations executed in the electronic device ED01 may be executed in one or a plurality of the electronic devices (ED02, ED04, and ED08). In an example case in which the electronic device ED01 needs to perform a function or service, the electronic device ED01 may request one or a plurality of electronic devices to perform part of the whole of the function or service, instead of performing the function or service. The one or a plurality of the electronic devices receiving the request may perform additional function or service related to the request, and transmit a result of the performance to the electronic device ED01. To this end, cloud computing, distributed computing, and/or client-server computing technology may be used.

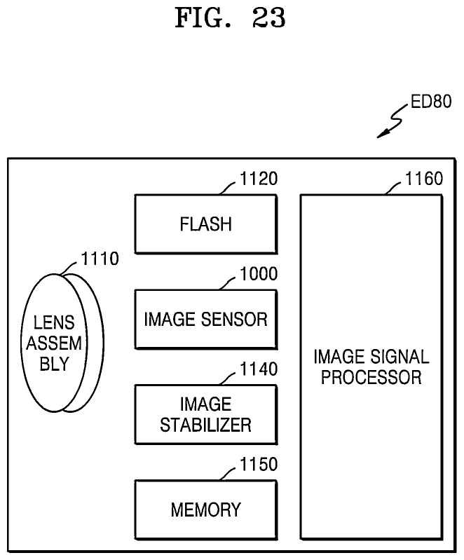

FIG. 23 is a block diagram illustrating an example of the camera module ED80 included in the electronic device ED01. Referring to FIG. 23, the camera module ED80 may include a lens assembly 1110, a flash 1120, the image sensor 1000, an image stabilizer 1140, a memory 1150 (e.g., a buffer memory, etc.), and/or an image signal processor 1160. The lens assembly 1110 may collect light emitted from a subject for image capturing. The camera module ED80 may include a plurality of lens assemblies 1110, and in this case, the camera module ED80 may include a dual camera, a 360 degrees camera, or a spherical camera. Some of the lens assemblies 1110 may have the same lens attributes (a viewing angle, a focal length, auto focus, F Number, optical zoom, and the like), or different lens attributes. The lens assembly 1110 may include a wide angle lens or a telescopic lens.

The flash 1120 may emit light used to reinforce light emitted or reflected from a subject. The flash 1120 may emit visible light or infrared light. The flash 1120 may include one or a plurality of light-emitting diodes (a red-green-blue (RGB) LED, a white LED, an infrared LED, an ultraviolet LED, and the like), and/or a xenon lamp. The image sensor 1000 may include the image sensor of FIG. 1, and convert light emitted or reflected from the subject and transmitted through the lens assembly 1110 into electrical signals, thereby obtaining an image corresponding to the subject.

The image stabilizer 1140 may move, in response to a movement of the camera module ED80 or an electronic device ED01 including the same, one or a plurality of lenses included in the lens assembly 1110 or the image sensor 1000 in a particular direction or may compensate a negative effect due to the movement by controlling (adjusting a read-out timing, and the like) the movement characteristics of the image sensor 1000. According to an embodiment, the image stabilizer 1140 may detect a movement of the camera module ED80 or the electronic device ED01 by using a gyro sensor (or an acceleration sensor arranged inside or outside the camera module ED80. The image stabilizer 1140 may be implemented in an optical form.

The memory 1150 may store a part or entire data of an image obtained through the image sensor 1000 for a subsequent image processing operation. In an example case in which a plurality of images are obtained at high speed, only low resolution images are displayed while the obtained original data (Bayer-Patterned data, high resolution data, and the like) is stored in the memory 1150. Then, the memory 1150 may be used to transmit the original data of a selected (user selection, and the like) image to the image signal processor 1160. The memory 1150 may be incorporated into the memory ED30 of the electronic device ED01, or configured to be an independently operated separate memory.

The image signal processor 1160 may perform image processing on the image obtained through the image sensor 1000 or the image data stored in the memory 1150. The image processing may include depth map generation, three-dimensional modeling, panorama generation, feature point extraction, image synthesis, and/or image compensation (noise reduction, resolution adjustment, brightness adjustment, blurring, sharpening, softening, and the like). The image signal processor 1160 may perform control (exposure time control, or read-out timing control, and the like) on constituent elements (the image sensor 1000, and the like) included in the camera module ED80.

The image processed by the image signal processor 1160 may be stored again in the memory 1150 for additional processing or provided to external constituent elements (the memory ED30, the display device ED60, the electronic device ED02, the electronic device ED04, the server ED08, and the like) of the camera module ED80. The image signal processor 1160 may be incorporated into the processor ED20, or configured to be a separate processor operated independently of the processor ED20. In an example case in which the image signal processor 1160 is configured by a separate processor from the processor ED20, the image processed by the image signal processor 1160 may undergo additional image processing by the processor ED20 and then displayed through the display device ED60.

The image signal processor 1160 may receive two output signals independently from adjacent light-sensing cells in each pixel or subpixel of the image sensor 1000 and generate an automatic focus signal from a difference between the two output signals. The image signal processor 1160 may control the lens assembly 1110 to accurately apply the focus of the lens assembly 1110 on the surface of the image sensor 1000 based on the automatic focus signal.

The electronic device ED01 may further include one or more camera modules that have different characteristics or functions from each other. The camera module may include a component similar to the camera module ED80 of FIG. 23, and an image sensor provided therein may be implemented as a charged coupled device (CCD) sensor or complementary metal oxide semiconductor (CMOS) sensor any may include one or more image sensors selected from image sensors having different properties, such an RGB sensor, a black and white (BW) sensor, an infrared (IR) sensor, and an ultraviolet (UV) sensor. In this case, one of the camera modules ED80 may be a wide angle camera, and another may be a telescopic camera. Similarly, one of the camera modules ED80 may be a front side camera, and another may be a read side camera.

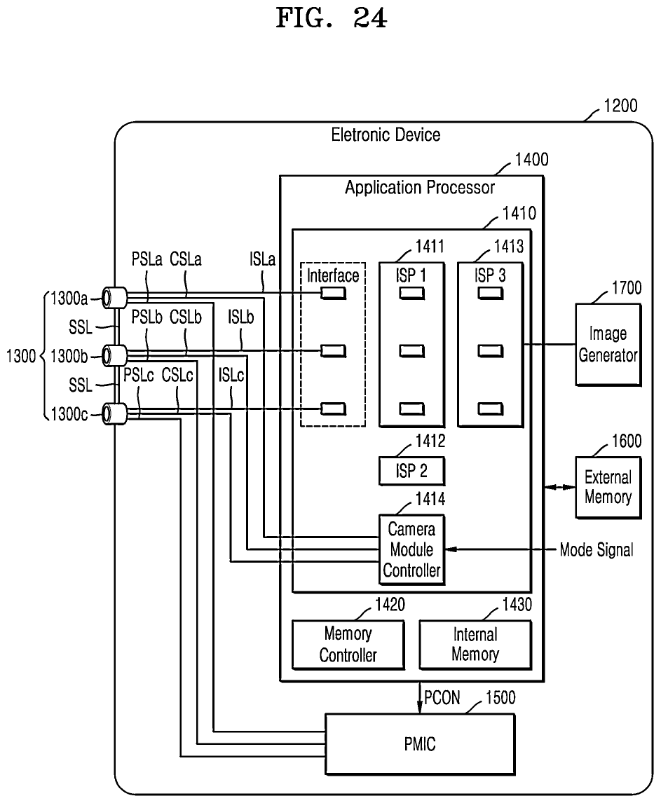

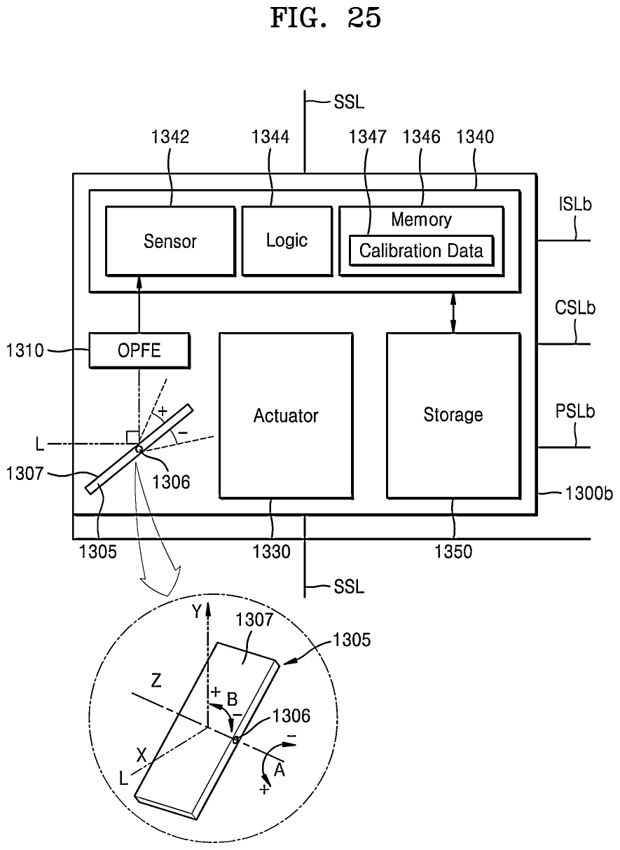

FIG. 24 is a block diagram of an electronic device including a multi-camera module, and FIG. 25 is a detailed block diagram of the multi-camera module of the electronic device illustrated in FIG. 24.

Referring to FIG. 24, an electronic device 1200 may include a camera module group 1300, an application processor 1400, a power management integrated circuit (PMIC) 1500, an external memory 1600, and an image generator 1700.

The camera module group 1300 may include a plurality of camera modules 1300a, 1300b, and 1300c. Although the drawings describe the embodiments in which three camera modules 1300a, 1300b, and 1300c are arranged, the embodiments are not limited thereto. In some embodiments, the camera module group 1300 may be modified and include only two camera modules. Also, in some embodiments, the camera module group 1300 may be modified and include n camera modules (n is a natural number of 4 or more.)

Hereinafter, the detailed configuration of the camera module 1300b is further described with reference to FIG. 25, and the descriptions may be applied to the other camera modules 1300a and 1300b as well according to embodiments.

With reference to FIG. 25, the camera module 1300b may include a prism 1305, an optical path folding element (OPFE) 1310, an actuator 1330, an image sensing device 1340, and a storage 1350.

The prism 1305 may include a reflector 1307 made of light reflective materials, and change a direction of light L incident from outside.

In some embodiments, the prism 1305 may change the direction of the light L incident in the first direction (X direction) to the second direction (Y direction) perpendicular to the first direction (X direction.) Further, the prism 1305 may rotate the reflector 1307 made of light reflective materials around a central axis 1306 in an A direction or rotate the central axis 1306 in a B direction to change the direction of the light L incident in the first direction (X direction) to the second direction (Y direction) perpendicular to the first direction. At this time, the OPFE 1310 may also move in the third direction (Z direction) perpendicular to the first direction (X direction) and the second direction (Y direction).

In some embodiments, as illustrated in the drawings, the maximum rotation angle of the prism 1305 in the A direction may be less than or equal to 15 degrees in +A direction, and greater than 15 degrees in −A direction; however, the embodiments are not limited thereto.

In some embodiments, the prism 1305 may move within 20 degrees in + or −B direction, or within 10 degrees to 20 degrees, or within 15 degrees to 20 degrees, and the movement may be made by the same angle in +B direction and in −B direction, or a similar angle, i.e., within an angle difference of 1 degree.

In some embodiments, the prism 1305 may move the reflector 1307 including light reflective materials in the third direction (e.g., the Z direction) parallel to the extending direction of the central axis 1306.

The OPFE 1310 may include an optical lens consisting of, for example, m groups (m is a natural number.) The m lens may change an optical zoom ratio of the camera module 1300b by moving in the second direction (Y direction.) In an example case in which the initial optical zoom ratio of the camera module 1300b is Z, and m optical lens included in the OPFE 1310 are moved, the optical zoom ratio of the camera module 1300b may be changed to 3Z, 5Z, or greater than 10Z.

The actuator 1330 may move the OPFE 1310 or the optical lens to a particular position. For example, the actuator 1330 may adjust the position of the optical lens so that an image sensor 1342 may be arranged at a focal length of the optical lens for accurate sensing.

The image sensing device 1340 may include the image sensor 1342, a control logic 1344, and a memory 1346. The image sensor 1342 may sense an image of an object by using the light L provided through the optical lens. The control logic 1344 may control overall operations of the camera module 1300b. For example, the control logic 1344 may control operations of the camera module 1300b according to control signals provided through a control signal line CSLb.

For example, the image sensor 1342 may include a color separation lens array or a nano optical lens array described above. The image sensor 1342 may receive more signals separated by wavelength per pixel by using a nano structure-based color separation array. Due to such effect, a light amount required for generating high-resolution and high-quality images at a low luminance may be secured.

The memory 1346 may store data required for operations of the camera module 1300b, such as calibration data 1347. The calibration data 1347 may include information necessary for the camera module 1300b to generate image data by using the light L provided from the outside. The calibration data 1347 may include, for example, information regarding degree of rotation, information regarding focal length, information regarding optical axis, etc. as described above. In an example case in which the camera module 1300b is implemented in the form of multi state camera in which a focal length varies according to a position of an optical lens, the calibration data 1347 may include information regarding a focal length according to a position (or a state) of the optical lens, and auto focusing.

The storage 1350 may store image data sensed through the image sensor 1342. The storage 1350 may be arranged outside of the image sensing device 1340, and may be implemented in a structure in which the storage 1350 and a sensor chip constituting the image sensing device 1340 are stacked. In some embodiments, the storage 1350 may be implemented as an electrically erasable programmable read-only memory (EEPROM), but the embodiments are not limited thereto.

With reference to FIGS. 24 and 25, in some embodiments, each of the plurality of camera modules 1300a, 1300b, and 1300c may include the actuator 1330. Accordingly, each of the plurality of camera modules 1300a, 1300b, and 1300c may include the same or similar calibration data 1347 according to an operation of the actuator 1330 included therein.

In some embodiments, one camera module (e.g., 1300b) of the plurality of camera modules 1300a, 1300b, and 1300c may be a folded lens camera module including the prism 1305 and the OPFE 1310 described above, and the rest of the camera modules (e.g., 1300a and 1300b) may be a vertical camera module which does not include the prism 1305 and the OPFE 1310. However, the embodiments are not limited thereto.

In some embodiments, one camera module (e.g., 1300c) of the plurality of camera modules 1300a, 1300b, and 1300c may be, for example, a vertical depth camera extracting depth information by using infrared ray (IR).

In some embodiments, at least two camera modules (e.g., 1300a and 1300b) of the plurality of camera modules 1300a, 1300b, and 1300c may have different fields of view. In this case, for example, at least two camera modules (e.g., 1300a and 1300b) of the plurality of camera modules 1300a, 1300b, and 1300c may have different optical lens, but the disclosure is not limited thereto.

Further, in some embodiments, fields of view of the plurality of camera modules 1300a, 1300b, and 1300c may be different from each other. In this case, optical lenses included in the plurality of camera modules 1300a, 1300b, and 1300c may also be different from each other, but the disclosure is not limited thereto.

In some embodiments, the plurality of camera modules 1300a, 1300b, and 1300c may be physically separated from each other. That is, a sensing area of one image sensor 1342 is not divided to be used by the plurality of camera modules 1300a, 1300b, and 1300c, but an independent image sensor 1342 may be arranged in each of the plurality of camera modules 1300a, 1300b, and 1300c.

With reference to FIG. 24, the application processor 1400 may include an image processing device 1410, a memory controller 1420, and an internal memory 1430. The application processor 1400 may be implemented separately from the plurality of camera modules 1300a, 1300b, and 1300c. For example, the application processor 1400 and the plurality of camera modules 1300a, 1300b, and 1300c may be implemented in separate semiconductor chips.

The image processing device 1410 may include a plurality of image processors 1411, 1412, and 1413 and a camera module controller 1414.

Image data generated from each of the camera modules 1300a, 1300b, and 1300c may be provided to the image processing device 1410 through image signal lines ISLa, ISLb, and ISLc separated from each other. Such image data transmission may be performed by, for example, a camera serial interface (CSI) based on a mobile industry processor interface (MPI), but the embodiments are not limited thereto.

The image data transmitted to the image processing device 1410 may be stored in the external memory 1600 before being transmitted to the image processors 1411 and 1412. The image data stored in the external memory 1600 may be provided to the image processor 1411 and/or the image processor 1412. The image processor 1411 may correct the received image data to generate a video. The image processor 1412 may correct the received image data to generate a still image. For example, the image processors 1411 and 1412 may perform a preprocessing operation such as color calibration, gamma correction, etc. on the image data.

The image processor 1411 may include sub-processors. In an example case in which the number of the sub-processors is the same as the number of the camera modules 1300a, 1300b, and 1300c, each sub-processor may process image data provided from one camera module. In an example case in which the number of the sub-processors is smaller than the number of the camera modules 1300a, 1300b, and 1300c, at least one of the sub-processors may process the image data provided from the plurality of camera modules by using a timing sharing process. Image data processed by the image processor 1411 and/or the image processor 1412 may be stored in the external memory 1600 before being transmitted to the image processor 1413. The image data stored in the external memory 1600 may be transmitted to the image processor 1412. The image processor 1412 may perform a post-processing operation such as noise correction, sharpen correction, etc. on the image data.

The image data processed by the image processor 1413 may be provided to the image generator 1700. The image generator 1700 may generate a final image by using the image data provided from the image processor 1413 according to image generating information or a mode signal.

Specifically, the image generator 1700 may generate an output image by merging at least some of image data generated from the camera modules 1300a, 1300b, and 1300c having different fields of view according to image generating information or a mode signal. Also, the image generator 1700 may generate an output image by selecting any one piece of image data generated from the camera modules 1300a, 1300b, and 1300c having different fields of view from each other according to image generating information or a mode signal.

In some embodiments, the image generating information may include a zoom signal or a zoom factor. Also, in some embodiments, the mode signal may be, for example, a signal based on a mode selected by a user.

In an example case in which the image generating information is a zoom signal (or a zoom factor), and each of the camera modules 1300a, 1300b, and 1300c have different fields of view from each other, the image generator 1700 may perform different operations according to a type of the zoom signal. In an example case in which the zoom signal is a first signal, the image generator 1700 may generate an output image by merging image data output from the camera module 1300a and image data output from the camera module 1300c, and then using the merged image signal and image data output from the camera module 1300b, which has not been used for data merging. In an example case in which the zoom signal is a second signal, which is different from the first signal, the image generator 1700 may not perform such image data merging, and generate an output image by selecting any one piece of image data output from each of the camera modules 1300a, 1300b, and 1300c. However, the embodiments are not limited thereto, and the method of processing image data may be modified in various ways, if necessary.

The camera module controller 1414 may provide a control signal to each of the camera modules 1300a, 1300b, and 1300c. The control signal generated from the camera module controller 1414 may be provided to the corresponding camera module 1300a, 1300b, and 1300c through the control signal lines CSLa, CSLb, and CSLc separated from each other.

In some embodiments, the control signal provided to the plurality of camera modules 1300a, 1300b, and 1300c from the camera module controller 1414 may include mode information according to the mode signal. Based on the mode information, the plurality of camera modules 1300a, 1300b, and 1300c may operate in a first operational mode and a second operational mode with respect to a sensing speed.

The plurality of camera modules 1300a, 1300b, and 1300c may generate an image signal at a first speed in the first operational mode (e.g., generate an image signal of a first frame rate), encode the image signal at a second speed which is higher than the first speed (e.g., encode an image signal of a second frame rate higher than the first frame rate), and transmit the encoded image signal to the application processor 1400. At this time, the second speed may be 30 times less than the first speed.

The application processor 1400 may store the received image signal, i.e., the encoded image signal in the internal memory 1430 or the storage 1600 outside the application processor 1400, read out from the memory 1430 or the storage 1600 the encoded image signal for decoding, and display image data generated based on the decoded image signal. For example, the image processors 1411 and 1412 of the image processing device 1410 may perform the decoding and may process image according to a decoded image signal.

The plurality of camera modules 1300a, 1300b, and 1300c may generate an image signal at a third speed which is lower than the first speed in the second operational mode (e.g., generate an image signal of a third frame rate lower than the first frame rate) and transmit the image signal to the application processor 1400. The image signal provided to the application processor 1400 may be a signal which has not been encoded. The application processor 1400 may perform the image processing on the received image signal or store the image signal in the memory 1430 or the storage 1600.

The PMIC 1500 may provide power, for example, a power voltage to each of the plurality of camera modules 1300a, 1300b, and 1300c. For example, the PMIC 1500 may provide, under the control by the application processor 1400, a first power to the camera module 1300a through a power signal line PSLa, a second power to the camera module 1300b through a power signal line PSLb, and a third power to the camera module 1300c through a power signal line PSLc.

The PMIC 1500 may generate power corresponding to each of the plurality of camera modules 1300a, 1300b, and 1300c in response to a power control signal PCON from the application processor 1400 and adjust a level of power. The power control signal PCON may include a power adjustment signal for each operational mode of the plurality of camera modules 1300a, 1300b, and 1300c. For example, the operational mode may include a low power mode, and in such a case, the power control signal PCON may include information regarding camera modules operating in the low power mode and a set power level. The levels of power provided to the plurality of camera modules 1300a, 1300b, and 1300c may be identical to or different from each other. Also, the power level may be changed dynamically.

According to the aforementioned embodiments, the image sensor may have a decreased reflectivity and improved light utilization efficiency by using the patterned anti-reflection layer. In addition, the image sensor according to the aforementioned embodiments may include the nano optical lens array which color-separates incident light without absorbing or reflecting the incident light and condenses the color-separated light at each pixel. The light utilization efficiency of the image sensor may be further improved by using the nano optical lens array.

The improved light utilization efficiency may facilitate reduction of size of each pixel or independent light-sensing cells in each pixel of the image sensor. Accordingly, the image sensor may have a higher resolution.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An image sensor comprising:
a substrate comprising a plurality of pixels sensing light;
a nano optical lens array provided on the substrate, the nano optical lens array comprising a plurality of color separation nano structures configured to separate incident light based on wavelengths and condense the separated light at respective corresponding pixels among the plurality of pixels; and
an anti-reflection layer provided on a light incidence surface of the nano optical lens array, the anti-reflection layer comprising a plurality of first nano patterns and a plurality of second nano patterns, which are periodically arranged in a two-dimensional manner,
wherein each of the plurality of second nano patterns are arranged between two adjacent first nano patterns, among the plurality of first nano patterns, and
a width of each of the plurality of first nano patterns is greater than a width of each of the plurality of second nano patterns.

2. The image sensor of claim 1, wherein the anti-reflection layer comprises a plurality of unit regions,
wherein the plurality of first nano patterns are arranged in the plurality of unit regions,
wherein the plurality of second nano patterns are arranged at boundaries of the plurality of unit regions, and
wherein the width of each of the plurality of first nano patterns is at least two times the width of each of the plurality of second nano patterns.

3. The image sensor of claim 1, wherein the anti-reflection layer comprises:
a first unit region, a second unit region, a third unit region, and a fourth unit region provided in a first row and a second row,
wherein the first unit region and the second unit region are adjacent to each other in the first row in a first direction, the third unit region and fourth unit region are adjacent to each other in the second row in the first direction, and the first row and the second row are adjacent to each other in a second direction, and
wherein the plurality of first nano patterns are provided in the first, second, third, and fourth unit regions, and the plurality of second nano patterns are provided at boundaries of the first, second, third, and fourth unit regions.

4. The image sensor of claim 1, wherein the width of each of the plurality of first nano patterns is about 150 nm to about 200 nm.

5. The image sensor of claim 1, wherein the width of each of the plurality of second nano patterns is about 75 nm to about 100 nm.

6. The image sensor of claim 1, wherein a distance between each of the plurality of first nano patterns and an adjacent second nano pattern, among the plurality of second nano patterns is about 20 nm to about 50 nm.

7. The image sensor of claim 2, wherein a width of each of the plurality of unit regions is about 200 nm to about 300 nm.

8. The image sensor of claim 2, wherein a fill factor of the plurality of first nano patterns in the plurality of unit regions is about 30% to about 70%, and the fill factor is a ratio of a cross-sectional area of the plurality of first nano patterns to a cross-sectional area of the plurality of unit regions.

9. The image sensor of claim 2, wherein the nano optical lens array comprises:
a first layer meta region and a second layer meta region provided on the first layer meta region,
wherein the first layer meta region comprises a plurality of first layer nano structures, and
wherein the second layer meta region comprises a plurality of second layer nano structures.

10. The image sensor of claim 9, wherein, at a peripheral portion of the image sensor, the first layer meta region and the second layer meta region of the nano optical lens array and the plurality of unit regions of the anti-reflection layer are shifted towards a central portion of the image sensor.

11. The image sensor of claim 10, wherein, at the peripheral portion of the image sensor, a shift distance of the plurality of unit regions is greater than a shift distance of the plurality of second layer meta regions, and the shift distance of the plurality of second layer meta regions is greater than a shift distance of the first layer meta region.

12. The image sensor of claim 1, wherein the anti-reflection layer comprises:
a first unit region in which incident light is incident at a first chief ray angle and a second unit region in which the incident light is incident at a second chief ray angle, which is greater than the first chief ray angle, and a width of each of the plurality of first nano patterns arranged in the second unit region is greater than a width of each of the plurality of first nano patterns arranged in the first unit region.

13. The image sensor of claim 1, wherein the anti-reflection layer comprises:
a first unit region in which incident light is incident at a first chief ray angle and a second unit region in which the incident light is incident at a second chief ray angle, which is greater than the first chief ray angle,
wherein a cross-section of each of the plurality of first nano patterns arranged in the first unit region is circular, and a cross-section of each of the plurality of first nano patterns arranged in the second unit region is elliptical.

14. The image sensor of claim 13, wherein the anti-reflection layer further comprises:
a third unit region in which the incident light is incident at a third chief ray angle, which is greater than the second chief ray angle,
wherein a cross-section of each of the plurality of first nano patterns arranged in the third unit region is elliptical, and an eccentricity of the plurality of first nano patterns arranged in the third unit region is greater than an eccentricity of the plurality of first nano patterns arranged in the second unit region.

15. The image sensor of claim 1, further comprising:
a color filter layer provided between the substrate and the nano optical lens array; and
a planarization layer provided between the color filter layer and the nano optical lens array.

16. The image sensor of claim 1, wherein the anti-reflection layer comprises at least one of AlO, HfO, SiN, SiO₂, AlOC, AlON, or AlOCN.

17. The image sensor of claim 1, wherein the anti-reflection layer comprises an inorganic material having a refractive index of about 1 to about 3.

18. A method of manufacturing an image sensor, the method comprising:
providing a nano optical lens array including a plurality of color separation nano structures on a substrate; and
providing an anti-reflection layer on the nano optical lens array,
wherein the arranging of the anti-reflection layer comprises:
arranging a dielectric layer on the nano optical lens array;
patterning a plurality of first nano patterns having a first width in the dielectric layer; and
patterning a plurality of second nano patterns having a second width less than the first width, in the dielectric layer,
wherein each of the plurality of second nano patterns are arranged between two adjacent first nano patterns, among the plurality of first nano patterns.

19. The method of claim 18, wherein the patterning of the plurality of first nano patterns comprises:
forming a photoresist layer on the dielectric layer;
selectively exposing a portion of an upper surface of the dielectric layer and patterning the photoresist layer using a photomask; and
forming the plurality of first nano patterns by etching the portion of the upper surface of the dielectric layer using the photoresist layer as an etching mask.

20. The method of claim 18, wherein the patterning of the plurality of second nano patterns comprises:
forming a photoresist layer on the dielectric layer;
forming an opening in the photoresist layer to selectively expose a portion of an upper surface of the dielectric layer and patterning the photoresist layer using a photomask;
forming a spacer layer on the photoresist layer to reduce a width of the opening of the photoresist layer; and
forming the plurality of second nano patterns by etching the portion of the upper surface of the dielectric layer using the photoresist layer and the spacer layer as an etching mask.
